(19) United States
(12) Patent Application Publication
(10) Pub. No.: US 2015/0171247 A1
(43) Pub. Date: Jun. 18, 2015

(54) SOLAR CELL MODULE

(71) Applicant: MITSUI CHEMICALS TOHCELLO, INC., Chiyoda-ku, Tokyo (JP)

(72) Inventors: Nobuhiro Maruko, Ichihara-shi (JP); Masaaki Odoi, Hitachinaka-shi (JP); Kazuhiro Yarimizu, Fujisawa-shi (JP); Shigenobu Ikenaga, Chiba-shi (JP)

(73) Assignee: MITSUI CHEMICALS TOHCELLO, INC., Chiyoda-ku, Tokyo (JP)

(21) Appl. No.: 14/390,437

(22) PCT Filed: Mar. 14, 2013
(86) PCT No.: PCT/JP2013/001718

§ 371 Date: Oct. 3, 2014

(30) Foreign Application Priority Data
Apr. 6, 2012 (JP) 2012-087735

(51) Int. Cl. H01L 31/048

(52) U.S. Cl. CPC H01L 31/0481

(57) ABSTRACT

A solar cell module (10) includes a light-incident surface protective member (14), a back surface protective member (15), solar cell elements (13), and an encapsulating layer (11) that encapsulates the solar cell elements (13) between the light-incident surface protective member (14) and the back surface protective member (15). The volume resistance per square centimeter at 85° C. between the light-incident surface protective member (14) and the solar cell element (13) is in a range of 1×10¹³ Ω·cm² to 1×10¹⁷ Ω·cm².

### TECHNICAL FIELD

The present invention relates to a solar cell module.

### BACKGROUND ART

In response to the increasing seriousness of global environmental issues, energy issues and the like, a solar cell is attracting attention as a clean energy-generating source with no concern over depletion. In a case in which a solar cell is used outdoors such as on the roof of a building, it is usual to use the solar cell in a solar cell module form.

Generally, the solar cell module is manufactured in the following order. First, a crystalline solar cell element (hereinafter, in some cases, also referred to as a power generation element or a cell, which indicates the same thing) formed of polycrystalline silicon or monocrystalline silicon, or a thin film-type solar cell element obtained by forming an extremely thin (several micrometers) film of amorphous silicon or crystalline silicon on a glass substrate or the like is manufactured. Next, to obtain a crystalline solar cell module, a light-incident surface protective member, an encapsulating material for a solar cell, the crystalline solar cell element, an encapsulating material for a solar cell, and a back surface protective member are sequentially laminated. Meanwhile, to obtain a thin film-based solar cell module, a thin film-type solar cell element, a sheet for encapsulating a solar cell, and a back surface protective member are sequentially laminated. After that, the solar cell module is manufactured using a lamination method or the like in which the above-described laminate is suctioned in a vacuum, heated and pressed. The solar cell module manufactured in the above-described manner is weather resistant and is also suitable for outdoor use such as on the roof of a building.

Examples of the encapsulating material for a solar cell include encapsulating materials described in Patent Documents 1 to 3. Patent Document 1 describes an ethylene vinyl acetate copolymer film as an encapsulating film for solar cell. Patent Document 2 describes an encapsulating material for a solar cell made of an α-olefin-based copolymer. Patent Document 3 describes a resin composition for an encapsulating material for a solar cell containing an ethylene/α-olefin copolymer.

### RELATED DOCUMENT

### Patent Document

[Patent Document 1] Japanese Unexamined Patent Publication No. 2010-53298

[Patent Document 2] Japanese Unexamined Patent Publication No. 2006-210906

[Patent Document 3] Japanese Unexamined Patent Publication No. 2010-258439

### DISCLOSURE OF THE INVENTION

Recently, in accordance with an increase in the size of a power generation system such as a mega solar power generation system, efforts are underway to increase the system voltage. Generally, the frame of a solar cell module is grounded, and thus the potential difference between the frame and the cell serves as the system voltage. Therefore, an increase in the system voltage leads to an increase in the potential difference between the frame and the cell. In addition, glass used for a light-incident surface protective member has a lower electric resistance compared with an encapsulating layer made of an encapsulating material for a solar cell, and a high voltage is generated between the light-incident surface protective member and the cell through the frame as well. That is, in a module connected in series, the potential difference between the cell and the module frame, and the potential difference between the cell and the glass surface sequentially increase from the ground side, and in the largest potential difference point, the potential difference of a high voltage of the system voltage is almost maintained. In a solar cell module used in the above-described state, a potential induced degradation (PID) phenomenon in which the output is significantly decreased and the characteristic deterioration occurs becomes likely to occur.

The invention has been made in consideration of the above-described circumstances, and provides a solar cell module capable of suppressing the occurrence of the PID phenomenon.

As a result of studies by the present inventors, it was found that, in a state of daytime power generation, there is a case in which the module temperature exceeds 80° C., and under this environment, characteristics deterioration called the above-described PID occurs. Therefore, the inventors found that, when the volume resistance at 85° C. between a light-incident surface protective member and a solar cell element is set in a specific range, it is possible to suppress the output decrease of a solar cell module even when a state in which a high voltage is applied between a cell and a module frame in the solar cell module is maintained, and to significantly suppress the occurrence of the PID phenomenon, and completed the invention.

That is, according to the invention, there is provided a solar cell module including a light-incident surface protective member; a back surface protective member, solar cell elements, and an encapsulating layer that encapsulates the solar cell elements between the light-incident surface protective member and the back surface protective member, in which a volume resistance per square centimeter at 85° C. between the light-incident surface protective member and the solar cell element is in a range of 1×10¹³ Ω·cm² to 1×10¹⁷ Ω·cm².

According to the invention, a solar cell module capable of suppressing the occurrence of a PID phenomenon is provided.

### BRIEF DESCRIPTION OF THE DRAWINGS

The above-described object, other objects, characteristics and advantages will be further clarified using preferable embodiments described below and the following drawings attached to the embodiments.

FIG. 1 is a cross-sectional view schematically illustrating an embodiment of a solar cell module of the invention.

FIG. 2 is a plan view schematically illustrating a configuration example of a light-incident surface and a back surface of a solar cell element.

### DESCRIPTION OF EMBODIMENTS

Hereinafter, the embodiments of the invention will be described using the drawings. Further, in all the drawings, the same components will be given the same reference numerals, and the description thereof will not be repeated. In addition, “A to B” indicates “equal to or more than A and equal to or less than B” unless particularly otherwise described.

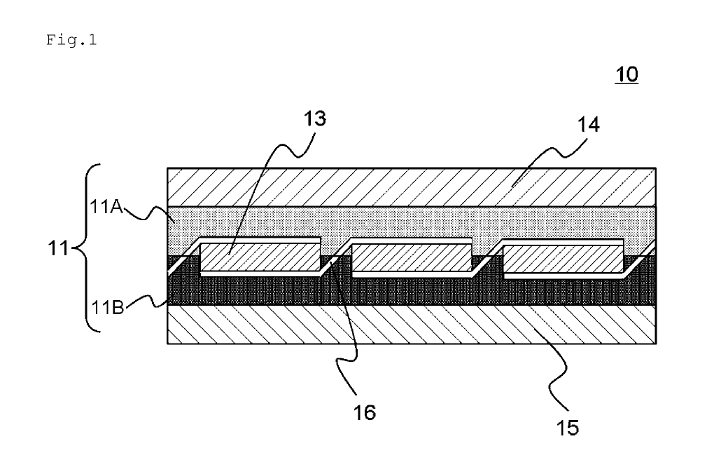

FIG. 1 is a cross-sectional view schematically illustrating an embodiment of a solar cell module of the invention. A solar cell module 10 illustrated in FIG. 1 includes a light-incident surface protective member 14, a back surface protective member 15, solar cell elements 13, and an encapsulating layer 11 that encapsulates the solar cell elements 13 between the light-incident surface protective member 14 and the back surface protective member 15. The volume resistance per square centimeter at 85° C. between the light-incident surface protective member 14 and the solar cell element 13 is in a range of 1×10¹³ Ω·cm² to 1×10¹⁷ Ω·cm².

The volume resistance refers to a volume resistance Rr per unit area, and when the actually-measured resistance value is represented by R1, and the solar cell element area is represented by S, the volume resistance is computed from Rr=R1*S. When the volume resistivity is represented by Rρ, and the encapsulating material thickness is represented by L, there is a relationship of Rr=Rρ*L.

As illustrated in FIG. 1, the solar cell module 10 includes a plurality of the solar cell elements 13 that are electrically connected to each other through interconnectors 16. FIG. 1 illustrates an example in which the solar cell elements 13 are connected to each other in series, but the solar cell elements 13 may be connected to each other in parallel. The light-incident surface protective member 14 and the back surface protective member 15 sandwich the solar cell elements 13, and the encapsulating layer 11 is filled between the protective members and the solar cell elements 13. The encapsulating layer 11 is made up of a light-incident surface-side encapsulating layer 11A and a back surface-side encapsulating layer 11B, the light-incident surface-side encapsulating layer 11A is in contact with electrodes formed on the light-incident surfaces of the solar cell elements 13, and the back surface-side encapsulating layer 11B is in contact with electrodes formed on the back surfaces of the solar cell elements 13. The electrodes refer to collector members respectively formed on the light-incident surfaces and the back surfaces of the solar cell elements 13, and the electrodes include collector lines, tab-type busbars, a back surface electrode layer, and the like described below.

The volume resistance per square centimeter at 85° C. between the light-incident surface protective member 14 and the solar cell element 13 in the solar cell module 10 can be measured as described below.

Since the solar cell module 10 includes the plurality of the solar cell elements 13 connected to each other in series as illustrated in FIG. 1, a specimen including one solar cell element 13 is cut out using a water jet cutter or the like. Even in a case in which the solar cell elements 13 are connected to each other in parallel, similarly, a specimen including one solar cell element 13 may be cut out. Next, the back surface protective member 15 is peeled off. Therefore, a specimen having a configuration of the light-incident surface protective member 14/the light-incident surface-side encapsulating layer 11A/the solar cell element 13/the back surface-side encapsulating layer 11B is obtained. This specimen is mounted in a constant-temperature bath having a 85° C. atmosphere, one electrode (ground side) of a resistance measurement device is connected to the solar cell element 13, and the other electrode is connected to the other (the high-voltage electrode) of the light-incident surface protective member 14 through a conductive rubber piece having a size corresponding to the electrode, whereby the volume resistance between the light-incident surface protective member 14 and the solar cell element 13 can be measured.

To stabilize the measurement, it is preferable to use a guard electrode, and similar to the electrode, the guard electrode is used in close contact with glass through a conductive rubber piece. At this time, the electrode being used is preferably set using an electrode shape having a smaller size than the solar cell element 13. During the measurement, it is preferable to use a measurement apparatus and an electrode shape which are specified by the standards for measuring the volume resistance of a resin such as JIS or ASTM. As an apparatus being used for the resistance measurement, an apparatus that is ordinarily used to measure volume resistance can be used.

Strictly speaking, in this measurement, the total resistance of the light-incident surface protective member 14 and the light-incident surface-side encapsulating layer 11A is measured, but the volume resistance of soda glass that is generally used as the light-incident surface protective member 14 is a significantly small resistance compared with the resistance of the light-incident surface-side encapsulating layer 11A that is preferably used in the invention, and the measurement value is substantially equal to the resistance of the light-incident surface-side encapsulating layer 11A. However, in any measurements, in a case in which, after the application of a voltage, the measurement value is not stabilized, and the resistance value tends to continuously increase, the value measured after 1000 seconds is used.

The obtained resistance value R1 is substantially equal to the resistance of the light-incident surface-side encapsulating layer 11A. A standardized value is computed by multiplying the resistance value R1 by the solar cell element area S, and is defined as the volume resistance Rr per unit area.

The volume resistance Rr per square centimeter between the light-incident surface protective member 14 and the solar cell element 13 at 85° C. is in a range of 1×10¹³ Ω·cm² to 1×10¹⁷ Ω·cm², and preferably in a range of 1×10¹⁴ Ω·cm² to 1×10¹⁷ Ω·cm². When the volume resistance Rr per square centimeter between the light-incident surface protective member 14 and the solar cell element 13 at 85° C. is in a range of 1×10¹³ Ω·cm² to 1×10¹⁷ Ω·cm², there is a tendency that the time taken for the PID phenomenon to occur in a constant temperature and humidity test at 85° C. and 85% rh can be extended to 240 hours, or further to 500 hours or longer. In addition, when the volume resistance per square centimeter between the light-incident surface protective member 14 and the solar cell element 13 at 85° C. is in a range of 1×10¹⁴ Ω·cm² to 1×10¹⁷ Ω·cm², there is a tendency that the time taken for the PID phenomenon to occur at a high temperature of equal to or higher than 100° C., and furthermore, the time taken for the PID phenomenon to occur at a high voltage of equal to or more than 1000 V can be extended.

The volume resistance Rr per square centimeter between the light-incident surface protective member 14 and the solar cell element 13 at 85° C. can be controlled by setting the volume resistance of the light-incident surface-side encapsulating layer 11A in the above-described range. Therefore, the volume resistance Rr per square centimeter of the light-incident surface-side encapsulating layer 11A is preferably in a range of 1×10¹³ Ω·cm² to 1×10¹⁷ Ω·cm², more preferably in a range of 1×10¹⁴ Ω·cm² to 1×10¹⁷ Ω·cm², and still more preferably in a range of 1×10¹⁴ Ω·cm² to 1×10¹⁶ Ω·cm². In addition, when the volume resistance per square centimeter of the light-incident surface-side encapsulating layer 11A at 85° C. is equal to or more than 1×10¹⁴ Ω·cm², there is a tendency that the time taken for the PID phenomenon to occur at a high temperature of equal to or higher than 100° C., and furthermore, the time taken for the PID phenomenon to occur at a high voltage of equal to or more than 1000 V can be extended, which is preferable.

When the thickness of the light-incident surface-side encapsulating layer 11A and the volume resistivity measured at a temperature of 100° C. and an applied voltage of 500 V are controlled, the volume resistance per square centimeter of the light-incident surface-side encapsulating layer 11A at 85° C. can be set in the above-described range. When the volume resistance per square centimeter of the light-incident surface-side encapsulating layer 11A at 85° C. is equal to or more than 1×10¹³ Ω·cm², in a constant temperature and humidity test at 85° C. and 85% rh, it is possible to suppress the occurrence of the PID phenomenon for at least one day. When the volume resistance per square centimeter of the light-incident surface-side encapsulating layer 11A is equal to or less than 1×10¹⁷ Ω·cm², static electricity is not easily generated, and therefore the infusion of foreign matters into the solar cell module 10 is prevented, whereby it is possible to suppress a decrease in the power generation efficiency or the degradation of the long-term reliability.

The thickness of the light-incident surface-side encapsulating layer 11A is preferably at least equal to or less than 1 cm from the viewpoint of the size reduction of the module, and is preferably in a range of 50 μm to 1000 μm, and more preferably in a range of 100 μm to 800 μm from the viewpoint of handling.

Meanwhile, the thickness of the light-incident surface-side encapsulating layer 11A mentioned herein refers to the distance between the light-incident surface of the solar cell element 13 and the light-incident surface protective member 14.

The volume resistivity of the light-incident surface-side encapsulating layer 11A, which is measured at 100° C. and an applied voltage of 500 V, is preferably in a range of 1×10¹³ Ω·cm to 1×10¹⁸ Ω·cm. Then, it is possible to set the thickness of the light-incident surface-side encapsulating layer 11A to an easily-handled thickness of several hundred micrometers, and to set the volume resistance at 85° C. between the light-incident surface protective member 14 and the solar cell element 13 to be in a range of 1×10¹³ Ω·cm² to 1×10¹⁷ Ω·cm². The volume resistivity of the light-incident surface-side encapsulating layer 11A is preferably in a range of 1×10¹⁴ Ω·cm to 1×10¹⁸ Ω·cm, more preferably in a range of 5×10¹⁴ Ω·cm to 1×10¹⁸ Ω·cm, and still more preferably in a range of 1×10¹⁵ Ω·cm to 1×10¹⁸ Ω·cm. When the volume resistivity of the light-incident surface-side encapsulating layer 11A is equal to or more than 5×10¹⁴ Ω·cm, there is a tendency that the time taken for the PID phenomenon to occur in a constant temperature and humidity test at 85° C. and 85% rh can be extended.

Meanwhile, the volume resistivity of the encapsulating layer 11 (the light-incident surface-side encapsulating layer 11A and the back surface-side encapsulating layer 11B) in the invention can be measured on the basis of JIS K6911.

The thickness of the back surface-side encapsulating layer 11B may be equal to or different from the thickness of the light-incident surface-side encapsulating layer 11A; however, from the viewpoint of the size reduction of the module, the thickness is preferably at least equal to or less than 1 cm, and is preferably in a range of 50 μm to 1000 μm, and more preferably in a range of 150 μm to 800 μm from the viewpoint of handling.

The volume resistivity of the back surface-side encapsulating layer 11B, which is measured at a temperature of 100° C. and an applied voltage of 500 V, may be equal to or different from the volume resistivity of the light-incident surface-side encapsulating layer 11A. Therefore, the volume resistivity of the entire encapsulating layer 11, which is measured at 100° C. and an applied voltage of 500 V, may be in a range of 1×10¹³ Ω·cm to 1×10¹⁸ Ω·cm, is preferably in a range of 1×10¹⁴ Ω·cm to 1×10¹⁸ Ω·cm, and more preferably in a range of 5×10¹⁴ Ω·cm to 1×10¹⁸ Ω·cm.

The encapsulating layer 11 is formed of an encapsulating material for a solar cell S made of a resin composition. The encapsulating material for a solar cell S preferably has a sheet shape, and may or may not be crosslinked as necessary. Hereinafter, the encapsulating material for a solar cell S used for the formation of the encapsulating layer 11 will be described.

The encapsulating material for a solar cell S may be made up of a pair of a first encapsulating material for a solar cell S1 that forms the light-incident surface-side encapsulating layer 11A and a second encapsulating material for a solar cell S2 that forms the back surface-side encapsulating layer 11B. Hereinafter, the encapsulating material for a solar cell S can also be used as a collective term for the first encapsulating material for a solar cell S1 and the second encapsulating material for a solar cell S2.

At least the first encapsulating material for a solar cell S1 of the encapsulating material for a solar cell S has a volume resistivity, which is measured at a temperature of 100° C. and an applied voltage of 500 V on the basis of JIS K6911, preferably in a range of 1×10¹³ Ω·cm to 1×10¹⁸ Ω·cm, more preferably in a range of 1×10¹⁴ Ω·cm to 1×10¹⁸ Ω·cm, still more preferably in a range of 5×10¹⁴ Ω·cm to 1×10¹⁸ Ω·cm, and particularly preferably in a range of 1×10¹⁵ Ω·cm to 1×10¹⁸ Ω·cm when crosslinked through three-minute heating and pressurization at 150° C. and 250 Pa, and then 15-minute heating and pressurization at 150° C. and 100 kPa. When the volume resistivity of the first encapsulating material for a solar cell S1 crosslinked through three-minute heating and pressurization at 150° C. and 250 Pa, and then 15-minute heating and pressurization at 150° C. and 100 kPa is investigated, it is possible to investigate the volume resistivity of the light-incident surface-side encapsulating layer 11A in the solar cell module 10.

In addition, the second encapsulating material for a solar cell S2 may also have a volume resistivity, which is measured at a temperature of 100° C. and an applied voltage of 500 V on the basis of JIS K6911, in a range of 1×10¹³ Ω·cm to 1×10¹⁸ Ω·cm, more preferably in a range of 1×10¹⁴ Ω·cm to 1×10¹⁸ Ω·cm, still more preferably in a range of 5×10¹⁴ Ω·cm to 1×10¹⁸ Ω·cm, and particularly preferably in a range of 1×10¹⁵ Ω·cm to 1×10¹⁸ Ω·cm when crosslinked through three-minute heating and pressurization at 150° C. and 250 Pa, and then 15-minute heating and pressurization at 150° C. and 100 kPa. When the volume resistivity after being crosslinked through three-minute heating and pressurization at 150° C. and 250 Pa, and then 15-minute heating and pressurization at 150° C. and 100 kPa is investigated, it is possible to investigate the volume resistivity of the back surface-side encapsulating layer 11B in the solar cell module 10.

When the volume resistivity of at least the first encapsulating material for a solar cell S1 of the encapsulating material for a solar cell S is equal to or more than 4×10¹⁴ Ω·cm, there is a tendency that the time taken for the PID phenomenon to occur in a constant temperature and humidity test at 85° C. and 85% rh can be further extended. The volume resistivity of the entire encapsulating material for a solar cell S may satisfy the above-described range.

The encapsulating material for a solar cell S is preferably made of a resin composition containing a crosslinkable resin. Examples of the crosslinkable resin include olefin-based resins such as ethylene/α-olefin copolymers, high-density ethylene-based resins, low-density ethylene-based resins, middle-density ethylene-based resins, ultralow-density ethylene-based resins, propylene (co)polymers, 1-butene (co)polymers, 4-methyl-pentene-1 (co)polymers, ethylene/cyclic olefin copolymers, ethylene/α-olefin/cyclic olefin copolymers, ethylene/α-olefin/unconjugated polyene copolymers, ethylene/α-olefin/conjugated polyene copolymers, ethylene/aromatic vinyl copolymers, and ethylene/α-olefin/aromatic vinyl copolymers; ethylene/unsaturated carboxylic acid copolymers such as ethylene/unsaturated anhydrous carboxylic acid copolymers, ethylene/α-olefin/unsaturated anhydrous carboxylic acid copolymers, ethylene/epoxy-containing unsaturated compound copolymers, ethylene/α-olefin/epoxy-containing unsaturated compound copolymers, and ethylene/vinyl acetate copolymers; ethylene/acrylic acid copolymers, ethylene/methacrylic acid copolymers; ethylene/unsaturated carboxylic acid ester copolymers such as ethylene/ethyl acrylate copolymers, and ethylene/methyl methacrylate copolymers; unsaturated carboxylic acid ester (co)polymers such as (meth)acrylic acid ester (co)polymers; ionomer resins such as ethylene/acrylic acid metal salt copolymers, and ethylene/methacrylic acid metal salt copolymers; urethane-based resins, silicone-based resins, acrylic acid-based resins, methacrylic acid-based resins, cyclic olefin (co)polymers, α-olefin/aromatic vinyl compound/aromatic polyene copolymers, ethylene/α-olefin/aromatic vinyl compound/aromatic polyene copolymers, ethylene/aromatic vinyl compound/aromatic polyene copolymers, styrene-based resins, acrylonitrile/butadiene/styrene copolymers, styrene/conjugated diene copolymers, acrylonitrile/styrene copolymers, acrylonitrile/ethylene/α-olefin/unconjugated polyene/styrene copolymers, acrylonitrile/ethylene/α-olefin/conjugated polyene/styrene copolymers, methacrylic acid/styrene copolymers, ethylene terephthalate resins, fluororesins, polyester carbonate, polyvinyl chloride, polyvinylidene chloride, polyolefin-based thermoplastic elastomers, polystyrene-based thermoplastic elastomers, polyurethane-based thermoplastic elastomers, 1,2-polybutadiene-based thermoplastic elastomers, trans polyisoprene-based thermoplastic elastomers, polyethylene chloride-based thermoplastic elastomers, liquid crystalline polyesters, polylactic acids, and the like.

Among the above-described crosslinkable resins, olefin-based resins such as ethylene/α-olefin copolymers, low-density ethylene-based resins, middle-density ethylene-based resins, ultralow-density ethylene-based resins, propylene (co)polymers, 1-butene (co)polymers, 4-methyl-pentene-1 (co)polymers, ethylene/cyclic olefin copolymers, ethylene/α-olefin/cyclic olefin copolymers, ethylene/α-olefin/unconjugated polyene copolymers, ethylene/α-olefin/conjugated polyene copolymers, ethylene/aromatic vinyl copolymers, and ethylene/α-olefin/aromatic vinyl copolymers; ethylene/unsaturated carboxylic acid copolymers such as ethylene/unsaturated anhydrous carboxylic acid copolymers, ethylene/α-olefin/unsaturated anhydrous carboxylic acid copolymers, ethylene/epoxy-containing unsaturated compound copolymers, ethylene/α-olefin/epoxy-containing unsaturated compound copolymers, ethylene/acrylic acid copolymers, and ethylene/methacrylic acid copolymers; ethylene/unsaturated carboxylic acid ester copolymers such as ethylene/ethyl acrylate copolymers, unsaturated carboxylic acid ester (co)polymers, (meth)acrylic acid ester (co)polymers, and ethylene/methyl methacrylate copolymers; ionomer resins such as ethylene/acrylic acid metal salt copolymers, and ethylene/methacrylic acid metal salt copolymers; cyclic olefin (co)polymers, α-olefin/aromatic vinyl compound/aromatic polyene copolymers, ethylene/α-olefin/aromatic vinyl compound/aromatic polyene copolymers, ethylene/aromatic vinyl compound/aromatic polyene copolymers, acrylonitrile/butadiene/styrene copolymers, styrene/conjugated diene copolymers, acrylonitrile/styrene copolymers, acrylonitrile/ethylene/α-olefin/unconjugated polyene/styrene copolymers, acrylonitrile/ethylene/α-olefin/conjugated polyene/styrene copolymers, and methacrylic acid/styrene copolymers are preferred.

The above-described crosslinkable resin is preferably manufactured with no substantial use of a compound that reacts with a metallocene compound described below so as to form an ion pair. Alternatively, it is preferable to reduce metal components or the ion content by carrying out a decalcification treatment in which the resin is treated using an acid or the like after being manufactured. With any methods, a volume resistance of equal to or more than 1×10¹¹ Ω·cm² is obtained, and it is possible to form the encapsulating layer 11 having excellent electrical characteristics. The crosslinkable resin may be modified using a silane compound.

At least the first encapsulating material for a solar cell S1 is preferably made of a resin composition containing an ethylene/α-olefin copolymer as the crosslinkable resin. Then, it is possible to form the light-incident surface-side encapsulating layer 11A by crosslinking the resin composition containing the ethylene/α-olefin copolymer.

The second encapsulating material for a solar cell S2 may be formed of the same composition as the first encapsulating material for a solar cell S1, or may be formed of a different composition, and may contain the ethylene/α-olefin copolymer as the crosslinkable resin. Both the first encapsulating material for a solar cell S1 and the second encapsulating material for a solar cell S2 may contain the ethylene/α-olefin copolymer. Then, it is possible to form the entire encapsulating layer 11 by crosslinking the resin composition containing the ethylene/α-olefin copolymer.

The ethylene/α-olefin copolymer contained in the encapsulating material for a solar cell S is more preferably an ethylene/α-olefin copolymer made up of ethylene and an α-olefin having 3 to 20 carbon atoms. As the α-olefin, generally, it is possible to singly use an α-olefin having 3 to 20 carbon atoms, or to use a combination of two or more α-olefins having 3 to 20 carbon atoms. An α-olefin having 10 or less carbon atoms is preferred, and an α-olefin having 3 to 8 carbon atoms is particularly preferred. Specific examples of the above-described α-olefin include propylene, 1-butene, 1-pentene, 1-hexene, 3-methyl-1-butene, 3,3-dimethyl-1-butene, 4-methyl-1-pentene, 1-octene, 1-decene, 1-dodecene, and the like. Among the above-described α-olefins, propylene, 1-butene, 1-pentene, 1-hexene, 4-methyl-1-pentene, and 1-octene are preferred in terms of easy procurement. Meanwhile, the ethylene/α-olefin copolymer may be a random copolymer or a block copolymer, but is preferably a random copolymer from the viewpoint of flexibility.

As the ethylene/α-olefin copolymer, it is preferable to use an ethylene/α-olefin copolymer satisfying at least one of the following requirements a1) to a4).

a1) A content ratio of a structural unit derived from ethylene is in a range of 80 mol % to 90 mol %, and a content ratio of a structural unit derived from an α-olefin having 3 to 20 carbon atoms is in a range of 10 mol % to 20 mol %.

a2) MFR, which is on the basis of ASTM D1238 and measured under conditions of a temperature of 190° C. and a load of 2.16 kg, is in a range of 0.1 g/10 minutes to 50 g/10 minutes.

a3) A density, which is measured on the basis of ASTM D1505, is in a range of 0.865 g/cm³ to 0.884 g/cm³.

a4) A Shore A hardness, which is measured on the basis of ASTM D2240, is in a range of 60 to 85.

The ethylene/α-olefin copolymer used in the encapsulating material for a solar cell S preferably satisfies any two of the above-described requirements a1) to a4), more preferably satisfies any three of the above-described requirements a1) to a4), and particularly preferably satisfies the three requirements a1), a3), and a4). The ethylene/α-olefin copolymer particularly preferably satisfies all of the above-described requirements a1) to a4). Hereinafter, a1) to a4) will be described.

a1)

The ratio of a structural unit, which is contained in the ethylene/α-olefin copolymer and is derived from α-olefin having 3 to 20 carbon atoms (hereinafter, also referred to as “α-olefin unit”), is in a range of 10 mol % to 20 mol %, preferably in a range of 12 mol % to 20 mol %, more preferably in a range of 12 mol % to 18 mol %, and still more preferably in a range of 13 mol % to 18 mol %. When the content ratio of the α-olefin unit is set to equal to or more than 10 mol %, there is a tendency that a highly transparent encapsulating layer 11 can be obtained. In addition, since the flexibility is high, it is possible to suppress the occurrence of cracking in the solar cell element 13 or the chipping of the thin film electrode. On the other hand, when the content ratio of the α-olefin unit is equal to or less than 20 mol %, the encapsulating material for a solar cell can be easily made into a sheet, a sheet having favorable blocking resistance can be obtained, and it is possible to improve the heat resistance through crosslinking.

a2)

The melt flow rate (MFR) of the ethylene/α-olefin copolymer, which is on the basis of ASTM D1238 and measured under conditions of 190° C. and a load of 2.16 kg, is generally in a range of 0.1 g/10 minutes to 50 g/10 minutes, preferably in a range of 2 g/10 minutes to 50 g/10 minutes, more preferably in a range of 10 g/10 minutes to 50 g/10 minutes, still more preferably in a range of 10 g/10 minutes to 40 g/10 minutes, particularly preferably in a range of 12 g/10 minutes to 27 g/10 minutes, and most preferably in a range of 15 g/10 minutes to 25 g/10 minutes. The MFR of the ethylene/α-olefin copolymer can be adjusted by adjusting the polymerization temperature and the polymerization pressure during a polymerization reaction described below, the molar ratio between the monomer concentration of ethylene and the α-olefin and the hydrogen concentration in a polymerization system, and the like.

(Calender Molding)

When the MFR is in a range of equal to or more than 0.1 g/10 minutes and less than 10 g/10 minutes, it is possible to manufacture a sheet through calender molding. When the MFR is in a range of equal to or more than 0.1 g/10 minutes and less than 10 g/10 minutes, the fluidity of the resin composition containing the ethylene/α-olefin copolymer is low, and therefore it is possible to prevent a lamination apparatus from being contaminated by the molten resin extracted when the sheet is laminated together with the cell element, which is preferable.

(Extrusion Molding)

When the MFR is equal to or more than 2 g/10 minutes, and is preferably equal to or more than 10 g/10 minutes, the fluidity of the resin composition containing the ethylene/α-olefin copolymer is improved, and it is possible to improve the productivity during sheet extrusion molding.

When the MFR is set to equal to or less than 50 g/10 minutes, the molecular weight is increased so that it is possible to suppress the adhesion to a roller surface of a chilled roller or the like, and therefore peeling is not required, and a sheet having a uniform thickness can be molded. Furthermore, since the resin composition becomes “stiff”, it is possible to easily mold a sheet having a thickness of equal to or more than 0.1 mm. In addition, since the crosslinking characteristic are improved during the lamination molding of the solar cell module, the crosslinkable resin is sufficiently crosslinked so that the degradation of the heat resistance can be suppressed.

When the MFR is equal to or less than 27 g/10 minutes, furthermore, it is possible to suppress drawdown during the sheet molding, to mold a sheet having a wide width, to further improve the crosslinking characteristics and the heat resistance, and to obtain the most favorable sheet of the encapsulating material for a solar cell.

Meanwhile, in a case in which the crosslinking treatment of the resin composition is not carried out in the lamination step of the solar cell module described below, the decomposition of the organic peroxide in the melt extrusion step has only a small effect, and therefore it is also possible to obtain a sheet through extrusion molding using a resin composition having a MFR in a range of equal to or more than 0.1 g/10 minutes and less than 10 g/10 minutes, and preferably in a range of equal to or more than 0.5 g/10 minutes and less than 8.5 g/10 minutes. In a case in which the content of the organic peroxide in the resin composition is equal to or less than 0.15 parts by weight, it is also possible to manufacture a sheet through extrusion molding at a molding temperature in a range of 170° C. to 250° C. using a resin composition having a MFR in a range of equal to or more than 0.1 g/10 minutes and less than 10 g/10 minutes while carrying out a silane modification treatment or a fine crosslinking treatment. When the MFR is in the above-described range, it is possible to prevent the lamination apparatus from being contaminated by a molten resin extracted when the sheet is laminated together with the solar cell element, which is preferable.

a3)

The density of the ethylene/α-olefin copolymer, which is measured on the basis of ASTM D1505, is in a range of 0.865 g/cm³ to 0.884 g/cm³, is preferably in a range of 0.866 g/cm³ to 0.883 g/cm³, more preferably in a range of 0.866 g/cm³ to 0.880 g/cm³, and still more preferably in a range of 0.867 g/cm³ to 0.880 g/cm³. The density of the ethylene/α-olefin copolymer can be adjusted using the balance between the content ratio of the ethylene unit and the content ratio of the α-olefin unit. That is, when the content ratio of the ethylene unit is increased, the crystallinity increases, and the ethylene/α-olefin copolymer having a high density can be obtained. On the other hand, when the content ratio of the ethylene unit is decreased, the crystallinity decreases, and the ethylene/α-olefin copolymer having a low density can be obtained. When the density of the ethylene/α-olefin copolymer is equal to or less than 0.884 g/cm³, it is possible to improve transparency and flexibility. On the other hand, when the density of the ethylene/α-olefin copolymer is equal to or more than 0.865 g/cm³, the encapsulating material for a solar cell can be easily made into a sheet, a sheet having favorable blocking resistance can be obtained, and it is possible to improve the heat resistance.

a4)

The Shore A hardness of the ethylene/α-olefin copolymer, which is measured on the basis of ASTM D2240, is in a range of 60 to 85, preferably in a range of 62 to 83, more preferably in a range of 62 to 80, and still more preferably in a range of 65 to 80. The Shore A hardness of the ethylene/α-olefin copolymer can be adjusted by controlling the content ratio or density of the ethylene unit in the ethylene/α-olefin copolymer within a numeric range described below. That is, the Shore A hardness becomes great in the ethylene/α-olefin copolymer having a high content ratio of the ethylene unit and a high density. On the other hand, the Shore A hardness becomes low in the ethylene/α-olefin copolymer having a low content ratio of the ethylene unit and a low density. When the Shore A hardness is equal to or more than 60, the encapsulating material for a solar cell can be easily made into a sheet, a sheet having favorable blocking resistance can be obtained, and furthermore, it is possible to improve the heat resistance. On the other hand, when the Shore A hardness is equal to or less than 85, it is possible to improve the transparency and the flexibility, and to facilitate sheet molding.

The ethylene/α-olefin copolymer contained in the encapsulating material for a solar cell S preferably further satisfies at least one of the following requirements a5) to a10), more preferably satisfies any two of the following requirements a5) to a10), still more preferably satisfies any three of the following requirements a5) to a10), and still more preferably satisfies all of the following requirements a5) to a10).

a5) The content of an aluminum element is in a range of 10 ppm to 500 ppm.

a6) A B value obtained from a ¹³C-NMR spectrum and the formula (1) described below is in a range of 0.9 to 1.5.

a7) The intensity ratio (Tαβ/Tαα) of Tαβ to Tαα in the ¹³C-NMR spectrum is equal to or less than 1.5.

a8) The molecular weight distribution Mw/Mn expressed by the ratio between the weight-average molecular weight (Mw) and the number-average molecular weight (Mn) measured using gel permeation chromatography (GPC) is in a range of 1.2 to 3.5.

a9) The content ratio of chlorine ions is equal to or less than 2 ppm.

a10) The extraction amount into methyl acetate is equal to or less than 5 weight %.

a5)

The content (residual amount) of an aluminum element (hereinafter, also expressed as “Al”) contained in the ethylene/α-olefin copolymer is preferably in a range of 10 ppm to 500 ppm, more preferably in a range of 20 ppm to 400 ppm, and still more preferably in a range of 20 ppm to 300 ppm. The content of Al is dependent on the concentration of an organic aluminumoxy compound or an organic aluminum compound being added during the polymerization process of the ethylene/α-olefin copolymer. When the content of Al is set to equal to or more than 10 ppm, it is possible to prevent the degradation of the electrical characteristics at a high temperature of, for example, 100° C. or the like. On the other hand, when the content of Al is set to equal to or less than 500 ppm, it is possible to obtain a sheet having a favorable appearance when the encapsulating material for a solar cell is made into a sheet.

As a method for controlling the above-described aluminum element contained in the ethylene/α-olefin copolymer, for example, it is possible to control the aluminum element contained in the ethylene/α-olefin copolymer by adjusting the concentrations of the organic aluminumoxy compound (II-1) and the organic aluminum compound (II-2) described in the below-described method for manufacturing the ethylene/α-olefin copolymer in a manufacturing step or the polymerization activity of the metallocene compound among the conditions for manufacturing the ethylene/α-olefin copolymer.

a6)

The B value of the ethylene/α-olefin copolymer, which is obtained from the ¹³C-NMR spectrum and the following equation (1), is preferably in a range of 0.9 to 1.5, more preferably in a range of 0.9 to 1.3, still more preferably in a range of 0.95 to 1.3, particularly preferably in a range of 0.95 to 1.2, and most preferably in a range of 1.0 to 1.2. The B value can be adjusted by changing a polymerization catalyst when the ethylene/α-olefin copolymer is polymerized. More specifically, the ethylene/α-olefin copolymer having a B value in the above-described numeric range can be obtained using the metallocene compound described below.

B value=[P_{OE}]/(2×[P_{O}]×[P_{E}]) (1)

(In the equation (1), [P_{E}] represents the proportion (molar fraction) of the structural unit derived from ethylene in the ethylene/α-olefin copolymer, [P_{O}] represents the proportion (molar fraction) of the structural unit derived from an α-olefin having 3 to 20 carbon atoms in the ethylene/α-olefin copolymer, and [P_{OE}] represents the proportion (molar fraction) of α-olefin-ethylene chains in all dyad chains.)

The B value is an index indicating the distribution state of the ethylene unit and the α-olefin unit in the ethylene/α-olefin copolymer, and can be obtained based on the reports by J. C. Randall (Macromolecules, 15, 353 (1982)), J. Ray (Macromolecules, 10, 773 (1977)). As the B value increases, the block chain of the ethylene unit or the α-olefin copolymer becomes shorter, and a high B value indicates that the distribution of the ethylene unit and the α-olefin unit is uniform and the composition distribution of copolymer rubber is narrow. Meanwhile, when the B value is set to equal to or more than 0.9, it is possible to obtain a sheet having a favorable appearance when the encapsulating material for a solar cell is made into a sheet.

a7)

The intensity ratio (Tαβ/Tαα) of Tαβ to Tαα of the ethylene/α-olefin copolymer in the ¹³C-NMR spectrum is preferably equal to or less than 1.5, more preferably equal to or less than 1.2, particularly preferably equal to or less than 1.0, and most preferably equal to or less than 0.7. Tαβ/Tαα can be adjusted by changing a polymerization catalyst when the ethylene/α-olefin copolymer is polymerized. More specifically, the ethylene/α-olefin copolymer having a Tαβ/Tαα in the above-described numeric range can be obtained using the metallocene compound described below.

Tαα and Tαβ in the ¹³C-NMR spectrum correspond to the peak intensities of “CH₂” in the structural unit derived from an α-olefin having 3 or more carbon atoms. More specifically, Tαα and Tαβ represent the peak intensities of two types of “CH₂” having different locations with respect to tertiary carbon atoms as illustrated in the following general formula (2).

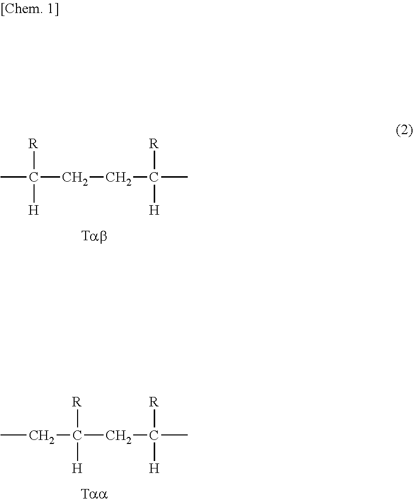

Tαβ/Tαα can be obtained in the following manner. The ¹³C-NMR spectrum of the ethylene/α-olefin copolymer is measured using an NMR measurement apparatus (for example, trade name “JEOL-GX270” manufactured by JEOL, Ltd.). The measurement is carried out using a mixed solution of hexachlorobutadiene and d6-benzene (at a volume ratio of 2/1) which has been adjusted to provide a specimen concentration of 5 weight % and a standard of d6-benzene (128 ppm) at 67.8 MHz and 25° C. The measured ¹³C-NMR spectrum is analyzed according to Lindemann-Adams' proposal (Analysis Chemistry, 43, p 1245 (1971)), J. C. Randall (Review Macromolecular Chemistry Physics, C29, 201 (1989)), and Tαβ/Tαα is obtained.

The intensity ratio (Tαβ/Tαα) of Tαβ to Tαα of the ethylene/α-olefin copolymer in the ¹³C-NMR indicates the coordination state of the α-olefin with respect to the polymerization catalyst during the polymerization reaction. In a case in which the α-olefin is coordinated with respect to the polymerization catalyst in a Tαβ form, the substituent in the α-olefin hinders the polymerization growth reaction of a polymer chain, and tends to promote the generation of a low molecular weight component. As a result, there is a tendency that the sheet becomes sticky and blocked, and the feeding property of the sheet deteriorates. Furthermore, since the low molecular weight component spreads on the sheet surface, adhesion is hindered, and the adhesiveness is degraded.

a8)

The molecular weight distribution Mw/Mn of the ethylene/α-olefin copolymer, which is expressed by the ratio of the weight-average molecular weight (Mw) to the number-average molecular weight (Mn) measured through gel permeation chromatography (GPC), is preferably in a range of 1.2 to 3.5, more preferably in a range of 1.7 to 3.0, still more preferably in a range of 1.7 to 2.7, and particularly preferably in a range of 1.9 to 2.4 since the encapsulating material for a solar cell can be easily made into a sheet, a sheet having favorable blocking resistance can be obtained, and it is possible to improve the adhesiveness through crosslinking. The molecular weight distribution Mw/Mn of the ethylene/α-olefin copolymer can be adjusted using the metallocene compound described below during the polymerization.

In the present specification, the ratio (Mw/Mn) of the weight-average molecular weight (Mw) to the number-average molecular weight (Mn) was measured in the following manner using a gel permeation chromatography instrument manufactured by Waters (trade name: “ALLIANCE GPC-2000”). Two “TSKgel GMH6-HT” (trade name) columns and two “TSKgel GMH6-HTL” (trade name) columns were used as separation columns. Regarding the column size, all columns had an inner diameter of 7.5 mm and a length of 300 mm, the column temperature was set to 140° C., o-dichlorobenzene (manufactured by Wako Pure Chemical Industries, Ltd.) was used as a mobile phase, and 0.025 weight % of BHT (manufactured by Takeda Pharmaceutical Company Limited) was used as an antioxidant. The mobile phase was moved at a rate of 1.0 ml/minute so as to set the specimen concentration to 15 mg/10 ml, the specimen injection amount was set to 500 μl, and a differential refractometer was used as a detector. Polystyrene manufactured by Tosoh Corporation was used as the standard polystyrene for the ethylene/α-olefin copolymer having a molecular weight of Mw<1000 and Mw>4×10⁶. In addition, polystyrene manufactured by Pressure Chemical Corporation was used as the standard polystyrene for the ethylene/α-olefin copolymer having a molecular weight of 1000≦Mw≦4×10⁶. The molecular weight was the value of the ethylene/α-olefin copolymer converted in accordance with each of the used α-olefins through universal correction.

a9)

The content ratio of chlorine ions in the ethylene/α-olefin copolymer, which is determined from an extraction liquid after a solid-phase extraction treatment through ion chromatography, is preferably equal to or less than 2 ppm, more preferably equal to or less than 1.5 ppm, and particularly preferably equal to or less than 1.2 ppm. The content ratio of chlorine ions can be adjusted by adjusting the structure and polymerization conditions of the metallocene compound described below. That is, when the polymerization activity of the catalyst is increased, the amount of a catalyst residue in the ethylene/α-olefin copolymer is decreased, and the ethylene/α-olefin copolymer having a content ratio of chlorine ions within the above-described range can be obtained. When the content ratio of chlorine ions in the ethylene/α-olefin copolymer is set to equal to or less than 2 ppm, it is possible to obtain the long-term reliability of the solar cell module. When a metallocene compound containing no chlorine atom is used, it is possible to obtain an ethylene/α-olefin copolymer substantially containing no chlorine ions.

The content ratio of chlorine ions in the ethylene/α-olefin copolymer can be measured by using an extraction liquid, which is obtained by, for example, accurately weighing approximately 10 g of the ethylene/α-olefin copolymer in a glass container that has been sterilized and washed using an autoclave or the like, adding 100 ml of ultrapure water, sealing the glass container, and then carrying out ultrasonic wave (38 kHz) extraction at room temperature for 30 minutes, and using an ion chromatography device manufactured by Dionex Ltd. (trade name “ICS-2000”).

a10)

Since it is possible to obtain a sheet that can be easily made into a sheet and has favorable blocking resistance, and furthermore to improve the adhesiveness as well, the extraction amount of the ethylene/α-olefin copolymer into methyl acetate is preferably equal to or less than 5 weight %, more preferably equal to or less than 4 weight %, still more preferably equal to or less than 3.5 weight %, and particularly preferably equal to or less than 2 weight %. A large extraction amount into methyl acetate indicates that a large amount of a low molecular weight component is contained in the ethylene/α-olefin copolymer and the molecular weight distribution or the composition distribution is wide. Therefore, it is possible to obtain the ethylene/α-olefin copolymer having a small extraction amount into methyl acetate by using the metallocene compound described below and adjusting the polymerization conditions. For example, when the metallocene compound having a decreased polymerization activity is discharged outside the polymerization system by shortening the polymerization retention time in a polymerization vessel, it is possible to suppress the generation of the low molecular weight component.

The extraction amount into methyl acetate is computed by, for example, accurately weighing approximately 10 g of the ethylene/α-olefin copolymer, carrying out Soxhlet extraction using an organic solvent which has a low boiling point and serves as a poor solvent for the ethylene/α-olefin copolymer, such as methyl acetate or methyl ethyl ketone, at a temperature that is equal to or higher than the boiling point of each solvent, and using the weight difference of the ethylene/α-olefin copolymer before and after the extraction or the residue amount obtained after the extracted solvent is volatilized.

The ethylene/α-olefin copolymer can be manufactured using a variety of metallocene compounds described below as a catalyst. Examples of the metallocene compounds that can be used include the metallocene compounds described in Japanese Unexamined Patent Publication No. 2006-077261, Japanese Unexamined Patent Publication No. 2008-231265, Japanese Unexamined Patent Publication No. 2005-314680 and the like. However, a metallocene compound having a different structure from those of the metallocene compounds described in the above-described patent documents may also be used, and a combination of two or more metallocene compounds may also be used.

Examples of the polymerization reaction in which the metallocene compound is used include a method in which one or more monomers selected from ethylene, α-olefin, and the like are supplied in the presence of a catalyst for olefin polymerization made up of a well-known metallocene compound (compound (I)) of the related art and a promoter (compound (II)).

As the compound (II), it is possible to use at least one compound selected from a group consisting of the organic aluminumoxy compound (compound (II-1)), compounds that react with the compound (I) so as to form an ion pair (compound II-2), and an organic aluminum compound (compound (II-3)).

As the compound (II), for example, the metallocene compounds described in Japanese Unexamined Patent Publication No. 2006-077261, Japanese Unexamined Patent Publication No. 2008-231265, Japanese Unexamined Patent Publication No. 2005-314680 and the like can be used. However, a metallocene compound having a different structure from those of the metallocene compounds described in the above-described patent documents may also be used. The above-described compounds may be individually injected into a polymerization atmosphere or be brought into contact with each other in advance and then injected into a polymerization atmosphere. Furthermore, for example, the compounds may be carried by the fine particle-form inorganic oxide carrier described in Japanese Unexamined Patent Publication No. 2005-314680 or the like.

Meanwhile, it is preferable to manufacture the ethylene/α-olefin copolymer with no substantial use of the compound (II-2), whereby the ethylene/α-olefin copolymer having excellent electrical characteristics can be obtained.

The polymerization of the ethylene/α-olefin copolymer can be carried out using any one of a well-known gas-phase polymerization method of the related art and a liquid-phase polymerization method such as a slurry polymerization method or a solution polymerization method. The polymerization is preferably carried out using the liquid-phase polymerization method such as the solution polymerization method. In a case in which the ethylene/α-olefin copolymer is manufactured by carrying out the copolymerization of ethylene and an α-olefin having 3 to 20 carbon atoms using the metallocene compound, the metallocene compound (I) is used in an amount in a range of, generally, 10⁻⁹ moles to 10⁻¹ moles, and preferably 10⁻⁸ moles to 10⁻² moles per a reaction volume of one liter.

The compound (II-1) is used in an amount in which the molar ratio [(II-1)/M] of the compound (II-1) to all transition metal atoms (M) in the compound (I) is generally in a range of 1 to 10000, and preferably in a range of 10 to 5000. The compound (II-2) is used in an amount in which the molar ratio [(II-2)/M] of the compound (II-2) to all the transition metal atoms (M) in the compound (I) is generally in a range of 0.5 to 50, and preferably in a range of 1 to 20. The compound (II-3) is used in an amount in a range of, generally, 0 millimoles to 5 millimoles, and preferably approximately 0 millimoles to 2 millimoles per a polymerization volume of one liter.

In the solution polymerization method, when ethylene and an α-olefin having 3 to 20 carbon atoms are copolymerized in the presence of the above-described metallocene compound, it is possible to efficiently manufacture an ethylene/α-olefin copolymer having a large content of a comonomer, a narrow composition distribution and a narrow molecular weight distribution. Here, the preliminary molar ratio of ethylene to the α-olefin having 3 to 20 carbon atoms is generally in a range of 10:90 to 99.9:0.1, preferably in a range of 30:70 to 99.9:0.1, and more preferably in a range of 50:50 to 99.9:0.1 (ethylene:α-olefin).

Examples of the α-olefin that can be used in the solution polymerization method also include polar group-containing olefins. Examples of the polar group-containing olefins include α,β-unsaturated carboxylic acids such as acrylic acid, methacrylic acid, fumaric acid and maleic anhydride, and metallic salts thereof such as sodium salts; α,β-unsaturated carboxylic acid esters such as methyl acrylate, ethyl acrylate, n-propyl acrylate, methyl methacrylate and ethyl methacrylate; vinyl esters such as vinyl acetate and vinyl propionate; unsaturated glycidyls such as glycidyl acrylate and glycidyl methacrylate; and the like. In addition, it is also possible to proceed with high-temperature solution polymerization in the co-presence of an aromatic vinyl compound in the reaction system. Examples of the aromatic vinyl compound include styrenes such as styrene, o-methyl styrene, m-methyl styrene, p-methyl styrene, o,p-dimethyl styrene, methoxy styrene, vinyl benzoate, vinyl methyl benzoate, vinyl benzyl acetate, hydroxy styrene, p-chloro styrene and divinyl benzene; 3-phenylpropylene, 4-phenylpropylene, α-methyl styrene, and the like. In addition, in the solution polymerization method, a cyclic olefin having 3 to 20 carbon atoms, for example, cyclopentene, cycloheptene, norbornene or 5-methyl-2-norbornene may be jointly used.

The “solution polymerization method” is a collective term for all methods in which polymerization is carried out in a state in which a polymer is dissolved in an inert hydrocarbon solvent described below. In the solution polymerization method, from the viewpoint of practical productivity, the polymerization temperature is generally in a range of 0° C. to 200° C., preferably in a range of 20° C. to 190° C., and more preferably in a range of 40° C. to 180° C.

The polymerization pressure is generally in a range of normal pressure to 10 MPa (gauge pressure), and preferably in a range of normal pressure to 8 MPa (gauge pressure). Copolymerization can be carried out in all of a batch method, a semi-continuous method, and a continuous method. The reaction time (the average retention time in a case in which a copolymerization reaction is carried out using a continuous method) varies depending on the conditions such as the catalyst concentration and the polymerization temperature, and can be appropriately selected, but is generally in a range of one minute to three hours, and preferably in a range of ten minutes to 2.5 hours. Furthermore, it is also possible to carry out the polymerization in two or more phases with different reaction conditions. The molecular weight of the obtained ethylene/α-olefin copolymer can be adjusted by changing the concentration of hydrogen or the polymerization temperature in the polymerization system. Furthermore, the molecular weight of the ethylene/α-olefin copolymer can also be adjusted using the amount of the compound (II) being used. In a case in which hydrogen is added, the amount of hydrogen is appropriately in a range of approximately 0.001 NL to 5000 NL per kilogram of the ethylene/α-olefin copolymer being generated. In addition, a vinyl group and a vinylidene group present at the ends of a molecule in the obtained ethylene/α-olefin copolymer can be adjusted by increasing the polymerization temperature and extremely decreasing the amount of hydrogen being added.

A solvent used in the solution polymerization method is generally an inert hydrocarbon solvent, and is preferably a saturated hydrocarbon having a boiling point in a range of 50° C. to 200° C. at normal pressure. Specific examples thereof include aliphatic hydrocarbons such as pentane, hexane, heptane, octane, decane, dodecane and kerosene; and alicyclic hydrocarbons such as cyclopentane, cyclohexane and methylcyclopentane. Meanwhile, aromatic hydrocarbons such as benzene, toluene and xylene and halogenated hydrocarbons such as ethylene chloride, chlorobenzene and dichloromethane also belong to the scope of the “inert hydrocarbon solvent”, and the use thereof is not limited.

As described above, in the solution polymerization method, not only the organic aluminumoxy compound dissolved in the aromatic hydrocarbon, which was frequently used in the related art, but also modified methyl aluminoxane dissolved in an aliphatic hydrocarbon or an alicyclic hydrocarbon such as MMAO can be used. As a result, when the aliphatic hydrocarbon or the alicyclic hydrocarbon is employed as the solvent for the solution polymerization, it becomes possible to almost completely eliminate the possibility of the aromatic hydrocarbon being incorporated into the polymerization system or the ethylene/α-olefin copolymer being generated. That is, the solution polymerization method also has characteristics that the environmental load can be reduced and the influence on human health can be minimized. Meanwhile, to suppress the variation in properties, it is preferable to melt the ethylene/α-olefin copolymer obtained through the polymerization reaction and other components added as desired using an arbitrary method, and to knead, granulate and the like the ethylene/α-olefin copolymer and other components.

The encapsulating material for a solar cell S preferably contains a silane coupling agent such as an ethylenic unsaturated silane compound and a crosslinking agent such as an organic peroxide in addition to the above-described ethylene/α-olefin copolymer. The content of the silane coupling agent can be set in a range of 0.1 parts by weight to 5 parts by weight with respect to 100 parts by weight of the ethylene/α-olefin copolymer, but it is more preferable to set the content of the ethylenic unsaturated silane compound in a range of 0.1 parts by weight to 4 parts by weight with respect to 100 parts by weight of the ethylene/α-olefin copolymer. The content of the crosslinking agent can be set in a range of 0.1 parts by weight to 3 parts by weight with respect to 100 parts by weight of the ethylene/α-olefin copolymer, but it is more preferable to set the content of the organic peroxide in a range of 0.2 parts by weight to 3 parts by weight with respect to 100 parts by weight of the ethylene/α-olefin copolymer.

Particularly, it is still more preferable that 0.1 parts by weight to 3 parts by weight of the ethylenic unsaturated silane compound and 0.2 parts by weight to 2.5 parts by weight of the organic peroxide be contained with respect to 100 parts by weight of the ethylene/α-olefin copolymer in the encapsulating material for a solar cell S. When the content of the ethylenic unsaturated silane compound is equal to or more than 0.1 parts by weight, the adhesiveness improves. On the other hand, when the content of the ethylenic unsaturated silane compound is equal to or less than 5 parts by weight, the balance between the cost and the performance becomes favorable, and it is possible to obtain a sheet having a favorable appearance when the encapsulating material for a solar cell is made into a sheet. In addition, it is possible to prevent a decrease in the breakdown voltage of the encapsulating layer 11 during use, and to prevent the degradation of the moisture permeability and the adhesiveness. Furthermore, it is possible to form the encapsulating layer 11 having a favorable appearance.

A well-known ethylenic unsaturated silane compound of the related art can be used as the ethylenic unsaturated silane compound, and there is no particular limitation. Specific examples thereof that can be used include vinyltriethoxysilane, vinyltrimethoxysilane, vinyltris(β-methoxyethoxysilane), γ-glycidoxypropyltrimethoxysilane, γ-aminopropyl triethoxysilane and γ-methacryloxypropyl trimethoxysilane. Preferable examples thereof include γ-glycidoxypropyl methoxysilane, γ-aminopropyl triethoxysilane, γ-methacryloxypropyl trimethoxysilane and vinyltriethoxysilane all of which have favorable adhesiveness.

The organic peroxide is used as a radical initiator during the graft modification of the ethylenic unsaturated silane compound and the ethylene/α-olefin copolymer, and furthermore, is used as a radial initiator during a crosslinking reaction when the ethylene/α-olefin copolymer is lamination-molded to the solar cell module. When the ethylenic unsaturated silane compound is graft-modified into the ethylene/α-olefin copolymer, a solar cell module 10 having a favorable adhesiveness between the light-incident surface protective member 14, the back surface protective member 15, the solar cell element 13, and an electrode can be obtained. Furthermore, when the ethylene/α-olefin copolymer is crosslinked, a solar cell module 10 having excellent heat resistance and adhesiveness can be obtained.

There is no particular limitation regarding the organic peroxide that can be preferably used as long as the organic peroxide is capable of graft-modifying the ethylenic unsaturated silane compound into the ethylene/α-olefin copolymer or crosslinking the ethylene/α-olefin copolymer, and the one-minute half-life temperature of the organic peroxide is in a range of 100° C. to 170° C. in consideration of the balance between the productivity during extrusion sheet molding and the crosslinking rate during the lamination molding of the solar cell module. When the one-minute half-life temperature of the organic peroxide is equal to or higher than 100° C., in a case in which the encapsulating material for a solar cell is made into a sheet, it is possible to obtain a sheet having a favorable appearance with favorable productivity. In addition, it is also possible to improve the moisture resistance and the adhesiveness. Furthermore, it is also possible to prevent a decrease in the breakdown voltage of the encapsulating layer 11 during use. When the one-minute half-life temperature of the organic peroxide is equal to or lower than 170° C., it is possible to improve the productivity of the solar cell module 10 by making the encapsulating material for a solar cell into a sheet, and it is also possible to prevent the degradation of the heat resistance and adhesiveness of the encapsulating material for a solar cell S.

A well-known organic peroxide can be used as the organic peroxide. Specific examples of the preferable organic peroxide having a one-minute half-life temperature in a range of 100° C. to 170° C. include dilauroyl peroxide, 1,1,3,3-tetramethylbutyl peroxy-2-ethylhexanoate, dibenzoyl peroxide, t-amylperoxy-2-ethylhexanoate, t-butylperoxy-2-ethylhexanoate, t-butylperoxy isobutyrate, t-butylperoxy maleate, 1,1-di(t-amylperoxy)-3,3,5-trimethylcyclohexane, 1,1-di(t-amylpeoxy)cyclohexane, t-amylperoxy isononanoate, t-amylperoxy n-octoate, 1,1-di(t-butylperoxy)-3,3,5-trimethylcyclohexane, 1,1-di(t-butylperoxy)cyclohexane, t-butylperoxy isopropyl carbonate, t-butylperoxy-2-ethylhexylcarbonate, 2,5-dimethyl-2,5-di(benzoylperoxy)hexane, t-amyl-peroxybenzoate, t-butylperoxy acetate, t-butylperoxy isononanoate, 2,2-di(t-butylperoxy)butane, t-butylperoxy benzoate, and the like. Preferable examples thereof include dilauroyl peroxide, t-butylperoxy isopropyl carbonate, t-butyl peroxy acetate, t-butylperoxy isononanoate, t-butylperoxy-2-ethylhexyl carbonate, t-butylperoxy benzoate, and the like.

The encapsulating material for a solar cell S preferably contains at least one additive selected from a group consisting of an ultraviolet absorber, a light stabilizer, and a heat-resistant stabilizer. The incorporation amount of the above-described additives is preferably in a range of 0.005 parts by weight to 5 parts by weight with respect to 100 parts by weight of the ethylene/α-olefin copolymer. Furthermore, it is preferable to include at least two additives selected from the above-described three additives, and it is particularly preferable to include all three additives. When the incorporation amount of the additives is within the above-described range, an effect that improves the resistance against high temperature and high humidity, the resistance against heat cycles, weather resistance stability and heat resistance stability is sufficiently ensured, and it is possible to prevent the degradation of the transparency of the encapsulating material for a solar cell S or the adhesiveness between the light-incident surface protective member 14, the back surface protective member 15, the solar cell element 13, the electrode, and aluminum, which is preferable.

Specific examples of the ultraviolet absorber that can be used include benzophenone-based ultraviolet absorbers such as 2-hydroxy-4-n-octyloxylbenzophenone, 2-hydroxy-4-methoxybenzophenone, 2,2-dihydroxy-4-methoxybenzophenone, 2-hydroxy-4-methoxy-4-carboxybenzophenone, and 2-hydroxy-4-N-octoxybenzophenone; benzotriazole-based ultraviolet absorbers such as 2-(2-hydroxy-3,5-di-t-butylphenyl)benzotriazole and 2-(2-hydroxy-5-methylpheyl)benzotriazole; salicyclic acid ester-based ultraviolet absorbers such as phenyl salicylate and p-octyl phenyl salicylate.

Examples of the light stabilizer that is preferably used include hindered amine-based light stabilizers such as bis(2,2,6,6-tetramethyl-4-piperidyl)sebacate, poly[{6-(1,1,3,3-tetramethylbutyl)amino-1,3,5-triazine-2,4-diyl}{(2,2,6,6-tetramethyl-4-piperidyl)imino}hexamethylene{(2,2,6,6-tetramethyl-4-piperidyl)imino}]; hindered piperidine-based compounds, and the like.

Specific examples of the heat-resistant stabilizer include phosphite-based heat-resistant stabilizers such as tris(2,4-di-tert-butylphenyl)phosphite, bis[2,4-bis(1,1-dimethylethyl)-6-methylphenyl]ethyl ester phosphite, tetrakis(2,4-di-tert-butylphenyl)[1,1-biphenyl]-4,4′-diylbisphosphite and bis(2,4-di-tert-butylphenyl)pentaerythritol diphosphite; lactone-based heat-resistant stabilizers such as a reaction product of 3-hydroxy-5,7-di-tert-butyl-furan-2-one and o-xylene; hindered phenol-based heat-resistant stabilizers such as 3,3′,3″,5,5′,5″-hexa-tert-butyl-a,a′,a″-(methylene-2,4,6-triyl)tri-p-cresole, 1,3,5-trimethyl-2,4,6-tris(3,5-di-tert-butyl-4-hydroxyphenyl)benzylbenzene, pentaerythritol tetrakis[3-(3,5-di-tert-butyl-4-hydroxyphenyl)propionate], octadecyl-3-(3,5-di-tert-butyl-4-hydroxyphenyl)propionate, and thiodiethylene bis[3-(3,5-di-tert-butyl-4-hydroxyphenyl)propionate]; sulfur-based heat-resistant stabilizers; amine-based heat-resistant stabilizers; and the like. In addition, it is possible to use only one of the above-described heat-resistant stabilizers or a combination of two or more heat-resistant stabilizers. Among the above-described heat-resistant stabilizers, the phosphite-based heat-resistant stabilizers and the hindered phenyl-based heat-resistant stabilizers are preferred.

The encapsulating material for a solar cell S can appropriately contain a variety of components other than the components described above in detail within the scope of the purpose of the invention. For example, other than the ethylene/α-olefin copolymer, a variety of polyolefins, styrene-based or ethylene-based block copolymers, propylene-based polymers, and the like can be included. The content of the above-described components may be in a range of 0.0001 parts by weight to 50 parts by weight, and preferably in a range of 0.001 parts by weight to 40 parts by weight with respect to 100 parts by weight of the ethylene/α-olefin copolymer. In addition, it is possible to appropriately include one or more additives selected from a variety of resins other than polyolefins and/or a variety of rubbers, a plasticizer, a filler, a pigment, a dye, an antistatic agent, an antimicrobial agent, an antifungal agent, a flame retardant, a crosslinking aid, a dispersant and the like.

In a case in which the crosslinking aid is contained in the encapsulating material for a solar cell S, when the incorporation amount of the crosslinking aid is in a range of 0.05 parts by weight to 5 parts by weight with respect to 100 parts by weight of the ethylene/α-olefin copolymer, it is possible to provide an appropriate crosslinking structure, and to improve heat resistance, mechanical properties, and adhesiveness, which is preferable.

A well-known crosslinking aid that is ordinarily used for olefin-based resins can be used as the crosslinking aid. The crosslinking aid is a compound having two or more double bonds in the molecule. Specific examples thereof include monoacrylates such as t-butyl acrylate, lauryl acrylate, cetyl acrylate, stearyl acrylate, 2-methoxyethyl acrylate, ethylcarbitol acrylate and methoxytripropyl glycol acrylate; monomethacrylates such as t-butyl methacrylate, lauryl methacrylate, cetyl methacrylate, stearyl methacrylate, methoxyethylene glycol methacrylate and methoxypolyethylene glycol methacrylate; diacrylates such as 1,4-butanediol diacrylate, 1,6-hexanediol diacrylate, 1,9-nonanediol diacrylate, neopentyl glycol diacrylate, diethylene glycol diacrylate, tetraethylene glycol diacrylate, polyethylene glycol diacrylate, tripropylene glycol diacrylate and polypropylene glycol diacrylate; dimethacrylates such as 1,3-butanediol dimethacrylate, 1,6-hexanediol dimethacrylate, 1,9-nonanediol dimethacrylate, neopentyl glycol dimethacrylate, ethylene glycol dimethacrylate, diethylene glycol dimethacrylate, triethylene glycol dimethacrylate and polyethylene glycol dimethacrylate; triacrylates such as trimethylolpropane triacrylate, tetramethylol methane triacrylate and pentaerythritol triacrylate; trimethacrylates such as trimethylolpropane trimethacrylate and trimethylolethane trimethacrylate; tetraacrylates such as pentaerythritol tetraacrylate and tetramethylolmethane tetraacrylate; divinyl aromatic compounds such as divinyl-benzene and di-i-propenylbenzene; cyanurates such as triallyl cyanurate and triallyl isocyanurate; diallyl compounds such as diallyl phthalate; triallyl compounds; oximes such as p-quinone dioxime and p-p′-dibenzoyl quinone dioxime; and maleimides such as a phenyl maleimide. Among the above-described crosslinking aids, diacrylates; dimethacrylates, divinyl aromatic compounds, triacrylates such as trimethylol propane triacrylate, tetramethylol methane triacrylate and pentaerythritol triacrylate; trimethacrylates such as trimethylol propane trimethacrylate and trimethylolethane trimethacrylate; tetraacrylates such as pentaerythritol tetraacrylate and tetramethylolmethane tetraacrylate; cyanurates such as triallyl cyanurate and triallyl isocyanurate; diallyl compounds such as diallyl phthalate; triallyl compounds; oximes such as p-quinone dioxime and p-p′-dibenzoyl quinonedioxime: and maleimides such as a phenyl maleimide are more preferred. Furthermore, among the above-described crosslinking aids, triallyl isocyanurate is particularly preferred since the balance between the air bubble generation and crosslinking characteristics of the encapsulating layer 11 is most favorable.

In a preferable aspect of the encapsulating material for a solar cell S, the time (Tc90) taken for the torque to reach 90% of the maximum torque value measured using a curelastometer at 150° C. and an inverse velocity of 100 cpm is in a range of 8 minutes to 14 minutes. The time is more preferably in a range of 8 minutes to 13 minutes, and still more preferably in a range of 9 minutes to 12 minutes. When Tc90 is set to equal to or longer than 8 minutes, it is possible to obtain a sheet having a favorable appearance when the encapsulating material for a solar cell is made into a sheet. In addition, it is possible to prevent a decrease in the breakdown voltage of the encapsulating layer 11 during use. Furthermore it is possible to improve the moisture resistance and the adhesiveness. When Tc90 is set to equal to or shorter than 14 minutes, the time required for crosslinking becomes shorter, and it is possible to shorten the time for manufacturing the solar cell module 10.

In a preferable aspect of the encapsulating material for a solar cell S, the time taken for the minimum torque value to increase by 0.1 Nm after kneading is carried out using a microrheology compounder under conditions of 120° C. and 30 rpm is in a range of 10 minutes to 100 minutes. The time taken for the minimum torque value to increase by 0.1 Nm is more preferably in a range of 10 minutes to 90 minutes, and still more preferably in a range of 10 minutes to 80 minutes. When the time taken for the minimum torque value to increase by 0.1 Nm is set to equal to or longer than 10 minutes, it is possible to obtain a sheet having a favorable appearance when the encapsulating material for a solar cell is made into a sheet. In addition, it is possible to prevent a decrease in the breakdown voltage of the encapsulating layer 11 during use. Furthermore it is possible to improve the moisture resistance and the adhesiveness. When the time taken for the minimum torque value to increase by 0.1 Nm is set to equal to or shorter than 100 minutes, the crosslinking characteristics improve, and it is possible to improve the heat resistance and the adhesiveness to the light-incident surface protective member 14 (particularly, the glass plate).

An ordinarily-used method can be used as the method for manufacturing the encapsulating material for a solar cell S, but the encapsulating material for a solar cell is preferably manufactured through melting and blending using a kneader, a Banbury mixer, an extruder or the like. Particularly, manufacturing using an extruder capable of continuous production is preferred.

The thickness of the sheet-shaped encapsulating material for a solar cell S is generally in a range of 0.01 mm to 2 mm, preferably in a range of 0.05 mm to 1.5 mm, more preferably in a range of 0.1 mm to 1.2 mm, still more preferably in a range of 0.2 mm to 1 mm, further more preferably in a range of 0.3 mm to 0.9 mm, and most preferably in a range of 0.3 mm to 0.8 mm. When the thickness is within the above-described range, it is possible to suppress the breakage of the glass plate used as the light-incident surface protective member 14, the solar cell elements 13, thin film electrodes and the like during the lamination step and to sufficiently ensure light transmittance, thereby obtaining a great light power generation amount.

There is no particular limitation regarding the method for molding the encapsulating material for a solar cell S, and a variety of well-known molding methods (cast molding, extrusion sheet molding, inflation molding, injection molding, compression molding, calender molding and the like) can be employed. Particularly, a method is most preferred in which a composition of the ethylene/α-olefin copolymer and a variety of additives obtained through manual blending the ethylene/α-olefin copolymer, the ethylenic unsaturated silane compound, the organic peroxide, the ultraviolet absorber, the light stabilizer, the heat-resistant stabilizer, and if necessary, other additives in a bag such as a plastic bag or blending them using a stirring and mixing machine such as a Henschel mixer, a tumbler or a super mixer, is injected into an extrusion sheet molding hopper, and extrusion sheet molding is carried out while melting and kneading the mixture. The extrusion temperature is preferably in a range of 100° C. to 130° C. When the extrusion temperature is set to equal to or higher than 100° C., the productivity of the encapsulating material for a solar cell S can be improved. When the extrusion temperature is set to equal to or lower than 130° C., it is possible to obtain a sheet having a favorable appearance. In addition, it is possible to prevent a decrease in the breakdown voltage of the encapsulating layer 11 during use. Furthermore, it is possible to improve the moisture resistance and the adhesiveness.

In addition, in a case in which the MFR of the ethylene/α-olefin copolymer is, for example, equal to or less than 10 g/10 minutes, it is also possible to obtain the sheet-shaped encapsulating material for a solar cell S by carrying out calender molding using a calender molder in which a molten resin is rolled using a heated metal roller (calender roller) so as to produce a sheet or film having a desired thickness while melting and kneading the ethylene/α-olefin copolymer, the silane coupling agent, the organic peroxide, the ultraviolet absorber, the light stabilizer, the heat-resistant stabilizer, and other additives used if necessary.

A variety of well-known calender molders can be used as the calender molder, and it is possible to use a mixing roller, a three roller rubber calender or a four roller rubber calender. Particularly, I-type, S-type, inverse L-type, Z-type, and inclined Z-type calender rollers can be used as the four roller rubber calender. In addition, the ethylene-based resin composition is preferably heated to an appropriate temperature before being applied to the calender roll, and it is also one of preferable embodiments to install, for example, a Banbury mixer, a kneader, an extruder, or the like. Regarding the temperature range for the calender molding, the roll temperature is preferably set in a range of, ordinarily, 40° C. to 100° C.

In addition, in a case in which the encapsulating material for a solar cell S is made into a sheet, the surface of the sheet may be embossed. When the sheet surface of the encapsulating material for a solar cell S is decorated through an embossing process, it is possible to prevent blocking between the sheets or between the sheet-shaped encapsulating material for a solar cell S and other members. Furthermore, since embossing decreases the storage elastic modulus of the encapsulating material for a solar cell S, the embossed surface serves as cushions for the solar cell element 13 and the like during the lamination of the encapsulating material for a solar cell S and the solar cell element 13, and the breakage of the solar cell element 13 can be prevented.

The porosity P (%), which is expressed by the percentage ratio V_{H}/V_{A}×100 of the total volume V_{H} of the recess portions per unit area of the encapsulating material for a solar cell S to the apparent volume V_{A} of the sheet of the encapsulating material for a solar cell S is preferably in a range of 10% to 50%, more preferably in a range of 10% to 40%, and still more preferably in a range of 15% to 40%. Meanwhile, the apparent volume V_{A} of the sheet-shaped encapsulating material for a solar cell S can be obtained by multiplying the unit area by the maximum thickness of the encapsulating material for a solar cell. When the porosity P is equal to or more than 10%, a sufficient cushioning property can be obtained, and it is possible to prevent the cracking of the solar cell element 13. In addition, when the porosity P of the encapsulating material for a solar cell S is equal to or more than 10%, it is possible to ensure a sufficient air ventilation path, and thus it is possible to suppress air from remaining in the solar cell module 10 so as to deteriorate the appearance or to suppress the electrode being corroded due to moisture in the remaining air when the solar cell module is used for a long period of time. In addition, it is also possible to suppress a laminator being contaminated by air extracted outside from the respective members in the solar cell module 10. On the other hand, when the porosity P is set to equal to or lower than 80%, it is possible to prevent air from remaining in the solar cell module 10 by reliably exhausting air during pressurization in the lamination process. Therefore, it is possible to prevent the deterioration of the appearance of the solar cell module 10, to eliminate the concern of the electrode being corroded by moisture in the remaining air, and to obtain a sufficient adhering strength.

The porosity P can be obtained through the following calculation. The apparent volume V_{A} (mm³) of the embossed encapsulating material for a solar cell S is computed through the product of the maximum thickness tₘₐₓ(mm) and unit area (for example, 1 m²=1000×1000=10⁶ mm²) of the encapsulating material for a solar cell S as described in the following equation (3).

V_{A} (mm³)=tₘₐₓ(mm)×10⁶ (mm²) (3)

Meanwhile, the actual volume V₀ (mm³) of the unit area of the encapsulating material for a solar cell S is computed by applying the specific weight ρ (g/mm³) of a resin configuring the encapsulating material for a solar cell S and the actual weight W (g) of the encapsulating material for a solar cell S per unit area (1 m²) to the following equation (4).

V₀ (mm³)=W/ρ (4)

The total volume V_{H} (mm³) of the recess portions per unit area of the encapsulating material for a solar cell S is computed by subtracting the “actual volume V₀” from the “apparent volume V_{A} of the encapsulating material for a solar cell” as described in the following equation (5).

V_{H} (mm³)=V_{A}−V₀=V_{A}−(W/ρ) (5)

Therefore, the porosity (%) can be obtained in the following manner.

$$\begin{matrix}Porosity P ( \% ) = {V}_{H} / {V}_{A} \times 100 \\ = ( {V}_{A} - ( W / ρ ) ) / {V}_{A} \times 100 \\ = 1 - W / ( ρ \cdot {V}_{A} ) \times 100 \\ = 1 - W / ( ρ \cdot {t}_{max} \cdot {10}^{6} ) \times 100\end{matrix}$$

The porosity (%) can be obtained using the above-described equation, and can also be obtained by photographing a cross-section or embossed surface of the manufactured encapsulating material for a solar cell S using a microscope and then processing the image or the like.

The depth of the recess portion formed through the embossing process is preferably in a range of 20% to 95%, more preferably in a range of 50% to 95%, and still more preferably in a range of 65% to 95% of the maximum thickness of the encapsulating material for a solar cell S. There is a case in which the percentage ratio of the depth D of the recess portion to the maximum thickness tₘₐₓ of the sheet is called the “depth ratio” of the recess portion.

The depth of the recess portion formed by the embossing process indicates the depth difference D between the top portion of the protrusion portion and the bottom portion of the recess portion in the uneven surface of the sheet-shaped encapsulating material for a solar cell S formed through the embossing process. In addition, the maximum thickness tₘₐₓ of the encapsulating material for a solar cell indicates the distance from the top portion of the protrusion portion on one surface to the other surface (in the thickness direction of the encapsulating material for a solar cell) in a case in which only one surface of the encapsulating material for a solar cell S is embossed, and indicates the distance from the top portion of the protrusion portion on one surface to the top portion of the proportion portion on the other surface (in the thickness direction of the encapsulating material for a solar cell S) in a case in which both surfaces of the encapsulating material for a solar cell S are embossed.

The embossing process may be carried out on a single surface or on both surfaces of the encapsulating material for a solar cell S. In a case in which the depth of the recess portion formed by the embossing process is set to be large, the recess portions are preferably formed only on a single surface of the encapsulating material for a solar cell S. In a case in which the embossing process is carried out only on a single surface of the encapsulating material for a solar cell S, the maximum thickness tₘₐₓ of the encapsulating material for a solar cell is in a range of 0.01 mm to 2 mm, preferably in a range of 0.05 mm to 1 mm, more preferably in a range of 0.1 mm to 1 mm, still more preferably in a range of 0.15 mm to 1 mm, still more preferably in a range of 0.2 mm to 1 mm, still more preferably in a range of 0.2 mm to 0.9 mm, particularly preferably in a range of 0.3 mm to 0.9 mm, and most preferably in a range of 0.3 mm to 0.8 mm. When the maximum thickness tₘₐₓ of the encapsulating material for a solar cell is within the above-described range, in the lamination step, it is possible to suppress the breakage of glass used as the light-incident surface protective member 14, the solar cell element 13, the thin film electrode and the like, and to laminate-mold the solar cell module at a relatively low temperature, which is preferable. In addition, the encapsulating material for a solar cell S is capable of ensuring a sufficient light transmittance, and the solar cell module for which the above-described encapsulating material for a solar cell is used has a high light power generation amount.

The encapsulating material for a solar cell S can be used as an encapsulating material for a solar cell in a leaflet form that has been cut in accordance with the size of the solar cell module or in a roll form that can be cut in accordance with the size immediately before the solar cell module is produced. The encapsulating material for a solar cell S may be a single layer or multiple layers. The encapsulating material for a solar cell is preferably a single layer since the structure can be simplified so as to decrease the cost, the interface reflection between layers is extremely decreased, and light is effectively used.

There is no particular limitation regarding the light-incident surface protective member 14, but the light-incident surface protective member is located on the outermost surface layer of the solar cell module, and thus preferably has performances for ensuring long-term reliability for the outdoor exposure of the solar cell module including weather resistance, water repellency, contamination resistance, and mechanical strength. In addition, the light-incident surface protective member is preferably a sheet having a small optical loss and high transparency for the effective use of sunlight. Examples of the light-incident surface protective member 14 include a glass plate, a resin film, and the like.

In a case in which a glass plate is used as the light-incident surface protective member 14, the total light transmittance of the glass plate with respect to light having a wavelength in a range of 350 nm to 1400 nm is preferably equal to or more than 80%, and more preferably equal to or more than 90%. It is usual to use as the glass plate a white glass plate that only slightly absorbs the infrared region, but a blue glass plate has a small influence on the output characteristics of the solar cell module when the blue glass plate has a thickness of equal to or less than 3 mm. In addition, it is possible to obtain reinforced glass through a thermal treatment to increase the mechanical strength of the glass plate, but a float glass plate that has not been subjected to a thermal treatment may also be used. In addition, the light-incident surface side of the glass plate may be coated for antireflection to suppress reflection.

Examples of the resin film include a polyester resin, a fluorine resin, an acryl resin, a cyclic olefin (co)polymer, an ethylene-vinyl acetate copolymer, and the like. The resin film is preferably a polyester resin having excellent transparency, strength, cost and the like, and particularly preferably a polyethylene terephthalate resin, a fluorine resin having favorable weather resistance, or the like. Examples of the fluorine resin include an ethylene-tetrafluoroethylene copolymer (ETFE), a polyvinyl fluoride resin (PVF), a polyvinylidene fluoride resin (PVDF), a polytetrafluoroethylene resin (TFE), a fluorinated ethylene/propylene copolymer (FEP) and a polytrifluorochloroethylene resin (CTFE). The polyvinylidene fluoride resin is excellent from the viewpoint of weather resistance, and the ethylene/tetrafluoroethylene copolymer is excellent in terms of satisfying both weather resistance and mechanical strength. In addition, to improve the adhesiveness to materials configuring other layers such as an encapsulating material layer, it is desirable to carry out a corona treatment and a plasma treatment on the surface protective member. In addition, it is also possible to use a sheet that has been subjected to a stretching treatment, for example, a biaxially stretched polypropylene sheet to improve the mechanical strength.

The back surface protective member 15 does not need to be transparent, and there is no particular limitation. Since the back surface protective member is located on the outermost surface layer of the solar cell module 10, similar to the above-described light-incident surface protective member 14, the back surface protective member is required to have a variety of characteristics such as weather resistance and mechanical strength. Therefore, the back surface protective member 15 may be configured using the same materials as the light-incident surface protective member 14. That is, a variety of the above-described materials used as the material for the light-incident surface protective member 14 can also be used as a material for the back surface protective member 15. Particularly, it is possible to preferably use a polyester resin and glass. Since the back surface protective member 15 is not required to allow the penetration of sunlight, transparency required by the light-incident surface protective member 14 is not essentially required. Therefore, a reinforcement plate may be attached to increase the mechanical strength of the solar cell module 10 or to prevent strain and warpage caused by the temperature change. Examples of the reinforcement plate that can be preferably used include a steel plate, a plastic plate, a fiber reinforced plastic (FRP) plate, and the like.

There is no particular limitation regarding the solar cell element 13 used in the solar cell module 10 as long as the solar cell element is capable of generating power using a photovoltaic effect of a semiconductor. FIG. 1 illustrates an example in which a crystalline solar cell element is used as the solar cell element 13, but it is also possible to use a compound semiconductor group, II-VI group, or the like) solar cell, a wet-type solar cell, an organic semiconductor solar cell or the like. The crystalline solar cell element is formed of monocrystalline silicon, polycrystalline silicon or non-crystalline (amorphous) silicon, and among the above-described silicon types, a crystalline solar cell element formed of the polycrystalline silicon is more preferred from the viewpoint of the balance between power generation performance, cost, and the like.

Both the crystalline solar cell element and the compound semiconductor solar cell element have excellent characteristics as the solar cell element, but it is known that both solar cell elements are easily broken due to external stress, impact, and the like. Therefore, when the encapsulating layer 11 having excellent flexibility is used, stress, impact, and the like on the solar cell elements are absorbed, and the breakage of the solar cell element can be prevented. In the solar cell module 10, it is desirable that the light-incident surface-side encapsulating layer 11A be directly joined to the solar cell elements 13. In addition, when the encapsulating material for a solar cell has thermoplasticity, it is possible to relatively easily remove the solar cell element 13 even after the solar cell module is produced, and thus the recycling properties are excellent. When the encapsulating layer 11 is formed of an ethylenic resin composition, the encapsulating layer 11 has thermoplasticity throughout the entire area due to the thermoplasticity of an ethylenic resin, which is preferred from the viewpoint of the recycling properties.

In the solar cell element, generally, a collection electrode for extracting generated electricity is disposed. Examples of the collection electrode include a busbar electrode, a finger electrode, and the like. Generally, the collection electrode is disposed on the front and back surfaces of the solar cell element; however, when the collection electrode is disposed on the light-incident surface, it is necessary to dispose the collection electrode so as to prevent a decrease in the power generation efficiency as much as possible.

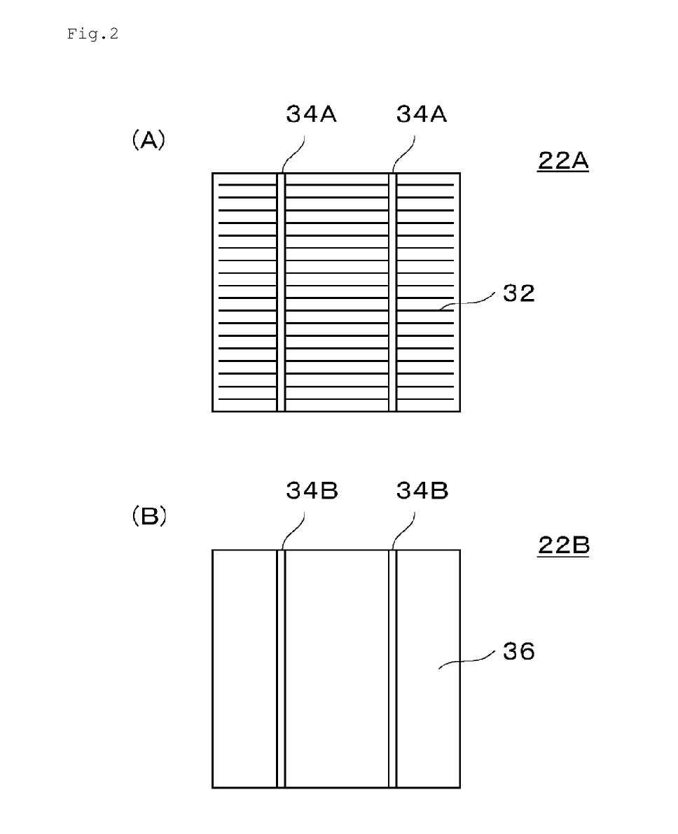

FIG. 2 is a plan view schematically illustrating a configuration example of the light-incident surface and the back surface of the solar cell element 13. FIG. 2 illustrates an example of a configuration of the light-incident surface 22A and the back surface 22B in the solar cell element 13. As illustrated in FIG. 2(A), a number of linearly-formed collector lines 32 and tab-type busbars (busbars) 34A which collect charge from the collector lines 32 and are connected to the interconnectors 16 (FIG. 1) are formed on the light-incident surface 22A of the solar cell element 13. In addition, as illustrated in FIG. 2(B), a conductive layer (back surface electrode) 36 is formed on the entire back surface 22B of the solar cell element 22, and tab-type busbars (busbars) 34B which collect charge from the conductive layer 36 and are connected to the interconnectors 16 (FIG. 1) are formed on the conductive layer. The line width of the collector line 32 is, for example, approximately 0.1 mm; the line width of the tab-type busbar 34A is, for example, in a range of approximately 2 mm to 3 mm; and the line width of the tab-type busbar 34B is, for example, in a range of approximately 5 mm to 7 mm. The thicknesses of the collector line 32, the tab-type busbar 34A, and the tab-type busbar 34B are, for example, in a range of approximately 20 μm to 50 μm respectively.

The collector line 32, the tab-type busbar 34A, and the tab-type busbar 34B preferably contain highly conductive metal. Examples of the highly conductive metal include gold, silver, copper, and the like, and silver, a silver compound, a silver-containing alloy, and the like are preferred in terms of the high conduction property or high corrosion resistance. The conductive layer 36 preferably contains not only highly conductive metal but also a highly light-reflecting component, for example, aluminum since light incident on the light-incident surface is reflected so as to improve the photoelectric conversion efficiency of the solar cell element. The collector line 32, the tab-type busbar 34A, the tab-type busbar 34B, and the conductive layer 36 are formed by applying a coating material of a conductive material containing the above-described highly conductive metal to the light-incident surface 22A or the back surface 22B of the solar cell element 22 to a coated film thickness of 50 μm through, for example, screen printing, then, drying the coated film, and if necessary, baking the coated film at a temperature in a range of, for example, 600° C. to 700° C.

Subsequently, the method for manufacturing the solar cell module 10 will be described. The method for manufacturing the solar cell module 10 includes (i) a step in which the light-incident surface protective member 14, the first encapsulating material for a solar cell S1, the solar cell elements 13, the second encapsulating material for a solar cell S2, and the back surface protective member 15 are laminated in this order, thereby forming a laminate, and (ii) a step in which the obtained laminate is pressurized and heated so as to be integrated.

In Step (i), in a case in which the encapsulating material for a solar cell S is embossed, a surface of the encapsulating material for a solar cell on which an uneven shape (embossed shape) is formed is preferably disposed to be on the solar cell element 13 side.

In Step (ii), the laminate obtained in Step (i) is heated and pressurized using a vacuum laminator or a hot press according to an ordinary method so as to be integrated (encapsulated). During the encapsulating, since the encapsulating material for a solar cell S has a high cushioning property, it is possible to prevent damage to the solar cell element. In addition, since the encapsulating material for a solar cell has favorable deaeration properties, air is not trapped, and it is possible to manufacture high-quality products with a favorable yield.

When the solar cell module 10 is manufactured, the ethylene/α-olefin-based resin composition configuring the encapsulating material for a solar cell S is cured through crosslinking. The crosslinking step may be carried out at the same time as Step (ii) or after Step (ii).

In a case in which the crosslinking step is carried out after Step (ii), in Step (ii), the laminate is heated and pressurized in a vacuum for three to six minutes under conditions of a temperature in a range of 125° C. to 160° C. and a vacuum pressure of equal to or less than 1333 Pa (10 Torr); and then, pressurization by the atmospheric pressure is carried out for approximately one minute to 15 minutes, thereby integrating the laminate. The crosslinking step carried out after Step (ii) can be carried out using an ordinary method, and, for example, a tunnel-type continuous crosslinking furnace may be used, or a tray-type batch crosslinking furnace may be used. In addition, the crosslinking conditions are generally a temperature in a range of 130° C. to 155° C. for approximately 20 minutes to 60 minutes.

Meanwhile, in a case in which the crosslinking step is carried out at the same time as Step (ii), it is possible to carry out the crosslinking step in the same manner as the case in which the crosslinking step is carried out after Step (ii) except for the fact that the heating temperature in Step (ii) is set in a range of 145° C. to 170° C. and the pressurization time at the atmospheric pressure is set in a range of six minutes to 30 minutes. Since the encapsulating material for a solar cell of the invention contains the specific organic peroxide, and thus has excellent crosslinking characteristics, the solar cell module does not need to pass through two phases of an adhering step in Step (ii), is capable of being completed at a high temperature within a short period of time, the crosslinking step carried out after Step (ii) may not be carried out, and it is possible to significantly improve the productivity of the module.

In any case, during the manufacturing of the solar cell module 10, the encapsulating material for a solar cell S is temporarily adhered to the solar cell element 13 or the light-incident surface protective member 14 and the back surface protective member 15 at a temperature at which a crosslinking agent is not substantially decomposed and the encapsulating material for a solar cell S is melted, and then sufficient adhering and crosslinking are carried out by increasing the temperature, thereby forming the encapsulating layer 11. An additive formulation with which a variety of conditions can be satisfied may be selected, and for example, the type and impregnation amount of the above-described crosslinking agent, the above-described crosslinking aid, and the like may be selected.

The gel fraction in the encapsulating layer 11 is set in a range of 50% to 95%, preferably in a range of 50% to 90%, still more preferably in a range of 60% to 90%, and most preferably in a range of 65% to 90% by laminating the encapsulating material for a solar cell S under the above-described crosslinking conditions so as to form the encapsulating layer 11. When the gel fraction is set to equal to or more than 50%, the encapsulating layer 11 having sufficient heat resistance can be formed, and it is possible to improve the adhesiveness in a constant temperature and humidity test at 85° C.×85% RH, a high-strength xenon radiation test at a black panel temperature of 83° C., a heat cycle test at a temperature in a range of −40° C. to 90° C., and a heat resistance test. When the gel fraction is set to equal to or less 95%, the flexibility of the encapsulating material for a solar cell S improves, and the temperature followability in the heat cycle test at a temperature in a range of −40° C. to 90° C. improves, whereby it is possible to prevent the occurrence of peeling or the like. The gel fraction in the encapsulating layer 11 can be computed by, for example, sampling one gram of the encapsulating layer 11 from the manufactured solar cell module 10, carrying out Soxhlet extraction for ten hours in boiling toluene, filtering an extraction liquid using a stainless steel mesh of 30 mesh, depressurizing and drying the mesh at 110° C. for eight hours, and measuring the residual amount on the mesh.

In addition, before Step (i), the back surface protective member 15 and the second encapsulating material for a solar cell S2 may be integrated in advance. Then, it is possible to shorten a step for cutting the back surface protective member 15 and the second encapsulating material for a solar cell S2 into a module size. In addition, it is also possible to shorten Step (i) by laying up the back surface protective member 15 and the second encapsulating material for a solar cell S2 in a form of an integrated sheet. In a case in which the second encapsulating material for a solar cell S2 and the back surface protective member 15 are integrated, the method for laminating the second encapsulating material for a solar cell S2 and the back surface protective member 15 is not particularly limited, and the laminating method is preferably a method in which a laminate is obtained through co-extrusion using a well-known melt extruder such as a casting molder, an extrusion sheet molder, an inflation molder or an injection molder; or a method in which one layer is melted or laminated by heating on the other layer that has been formed in advance, thereby obtaining a laminate.

The encapsulating layer 11 in the solar cell module 10 may be formed only of the encapsulating material for a solar cell S, but may have members other than the encapsulating material for a solar cell S (hereinafter, “other members”). Examples of the other members include a hard coated layer for protecting the front surface or the back surface, an adhering layer, an anti-reflection layer, a gas barrier layer, an anti-contamination layer, and the like. The other members can be classified based on the material into, for example, an ultraviolet-curable resin layer, a thermosetting resin layer, a polyolefin resin layer, a carboxylic acid-modified polyolefin resin layer, a fluorine-containing resin layer, a cyclic olefin (co)polymer layer, an inorganic compound layer, and the like.

There is no particular limitation regarding the disposition of the other members, and the other members are appropriately disposed at preferable locations in terms of the relationship with the object of the invention. That is, the other members may be disposed between pluralities of the first encapsulating materials for solar cell S1 so as to be disposed inside the light-incident surface-side encapsulating layer 11A, or may be disposed between pluralities of the second encapsulating materials for solar cell S2 so as to be disposed inside the back surface-side encapsulating layer 11B. In addition, the other members may be disposed on the outermost layer of the light-incident surface-side encapsulating layer 11A or the back surface-side encapsulating layer 11B, or may be provided at places other than what have been described above. In addition, the other members may be provided on only one of the light-incident surface-side encapsulating layer 11A and the back surface-side encapsulating layer 11B, or may be provided on both of the light-incident surface-side encapsulating layer 11A or the back surface-side encapsulating layer 11B. There is no particular limitation regarding the number of the other members, and an arbitrary number of other members can be provided, and the encapsulating layer 11 may include no other member.

In a case in which the other members are provided, the other members simply need to be laminated on the sheet-shaped encapsulating material for a solar cell in advance before Step (i), and the lamination method is not particularly limited, but is preferably a method in which a laminate is obtained through co-extrusion using a well-known melt extruder such as a casting molder, an extrusion sheet molder, an inflation molder or an injection molder; or a method in which one layer is melted or laminated by heating on another layer that has been formed in advance, thereby obtaining a laminate.

In addition, the encapsulating material for a solar cell and the back surface protective member may be laminated using a dry laminate method, a heat laminate method or the like in which an appropriate adhesive (for example, a maleic acid anhydride-modified polyolefin resin (product name “ADOMER (registered trademark)” manufactured by Mitsui Chemicals, Inc.), “MODIC (registered trademark)” manufactured by Mitsubishi Chemical Corporation or the like), a low- (non-) crystalline soft polymer such as an unsaturated polyolefin, an acrylic adhesive including an ethylene/acrylic acid ester/maleic acid anhydride-ternary copolymer (trade name “BONDINE (registered trademark)” manufactured by Sumika CdF Chemical Company Limited.), an ethylene/vinyl acetate-based copolymer, an adhesive resin composition containing what has been described above, or the like) is used. An adhesive having heat resistance in a range of approximately 120° C. to 150° C. is preferably used as the adhesive, and preferable examples thereof include polyester-based adhesives, and polyurethane-based adhesives. In addition, to improve the adhesiveness between both surfaces, for example, a silane-based coupling treatment, a titanium-based coupling treatment, a corona treatment, a plasma treatment or the like may be used.

In the solar cell module 10 manufactured in the above-described manner, the encapsulating layer 11 is excellent in terms of the balance between heat resistance and adhesiveness to a variety of module members such as the light-incident surface protective member 14, the back surface protective member 15, the thin film electrode, aluminum, the solar cell element 13, and the like, and furthermore, is excellent in terms of the balance among transparency, flexibility, appearance, weather resistance, volume resistivity, electrical insulating properties, moisture permeability, electrode corrosion properties, and process stability.

When several to several tens of the solar cell modules 10 manufactured in the above-described manner are connected in series so as to configure the solar cell system, the solar cell modules can be used not only for small-scale residential use of 50 V to 500 V but also for large-scale use called a mega solar power generation system of 600 V to 1000 V. For example, the solar cell module can be used for both indoor and outdoor use such as an outdoor mobile power supply for camping and the like, which is installed on the roofs of houses and an auxiliary power supply for automobile batteries. The solar cell module 10 of the invention is excellent in terms of productivity, power generation efficiency, service life, and the like, and thus a power generation facility produced using the above-described solar cell system is excellent in terms of cost, power generation efficiency, service life, and the like, has a high practical value, and is particularly preferable for long-term use.

Thus far, the embodiments of the invention have been described with reference to the accompanying drawings, but the embodiments are examples of the invention, and a variety of configurations other than the embodiments can also be employed.

### EXAMPLES

Hereinafter, the invention will be specifically described based on examples, but the invention is not limited to the examples.

(1) Measurement Method

[The Content Ratio of the Ethylene Unit and the α-Olefin Unit]

After a solution obtained by heating and melting 0.35 g of a specimen in 2.0 ml of hexachlorobutadiene was filtered using a glass filter (G2), 0.5 ml of deuterated benzene was added, and the mixture was injected into an NMR tube having an inner diameter of 10 mm. The ¹³C-NMR was measured at 120° C. using a JNM GX-400-type NMR measurement device manufactured by JEOL, Ltd. The cumulated number was set to equal to or more than 8000 times. The content ratio of the ethylene unit and the content ratios of the α-olefin unit in the copolymer were determined from the obtained ¹³C-NMR spectra.

[MFR]

The MFR of the ethylene/α-olefin copolymer was measured on the basis of ASTM D1238 under conditions of 190° C. and a load of 2.16 kg.

[Density]

The density of the ethylene/α-olefin copolymer was measured on the basis of ASTM D1505.

[Shore A Hardness]

After the ethylene/α-olefin copolymer was heated at 190° C. for four minutes and pressurized at 10 MPa, the ethylene/α-olefin copolymer was pressurized and cooled at 10 MPa to room temperature for five minutes, thereby obtaining a 3 mm-thick sheet. The Shore A hardness of the ethylene/α-olefin copolymer was measured on the basis of ASTM D2240 using the obtained sheet.

[The Content of the Aluminum Element]

After the ethylene/α-olefin copolymer was wet-decomposed, the volume was made to be constant using pure water, the amount of the aluminum element was determined using an ICP emission spectrometer (ICPS-8100 manufactured by Shimadzu Corporation), and the content of the aluminum element was obtained.

[B Value]

The “B value” of the ethylene/α-olefin copolymer was computed using the above-described ¹³C-NMR spectrum and the following formula (1).

B value=[POE]/(2×[PO]×[PE]) (1)

(In Formula (1), [PE] represents the proportion (molar fraction) of the structural unit derived from ethylene in the ethylene/α-olefin copolymer, [PO] represents the proportion (molar fraction) of the structural unit derived from an α-olefin having 3 to 20 carbon atoms in the ethylene/α-olefin copolymer, and [POE] represents the proportion (molar fraction) of α-olefin-ethylene chains in all dyad chains.)

[Tαβ/Tαα]

The “Tαβ/Tαα” of the ethylene/α-olefin copolymer was computed using the above-described ¹³C-NMR spectrum with reference to the description in the above-described documents.

[Molecular Weight Distribution (Mw/Mn)]

The weight-average molecular weight (Mw) and number-average molecular weight (Mn) of the ethylene/α-olefin copolymer were measured in the following manner using a gel permeation chromatography instrument manufactured by Waters (trade name: “ALLIANCE GPC-2000”), and Mw/Mn was computed. Two “TSKgel GMH6-HT” (trade name) columns and two “TSKgel GMH6-HTL” (trade name) columns were used as separation columns. Regarding the column size, all columns had an inner diameter of 7.5 mm and a length of 300 mm, the column temperature was set to 140° C., o-dichlorobenzene (manufactured by Wako Pure Chemical Industries, Ltd.) was used as a mobile phase, and 0.025 weight % of BHT (manufactured by Takeda Pharmaceutical Company Limited) was used as an antioxidant. The mobile phase was moved at a rate of 1.0 ml/minute so as to set the specimen concentration to 15 mg/10 ml, the specimen injection amount was set to 500 μl, and a differential refractometer was used as a detector. Polystyrene manufactured by Tosoh Corporation was used as the standard polystyrene for the ethylene/α-olefin copolymer having a molecular weight of Mw≦1000 and Mw≧4×10⁶. In addition, polystyrene manufactured by Pressure Chemical Corporation was used as the standard polystyrene for the ethylene/α-olefin copolymer having a molecular weight of 1000≦Mw≦4×10⁶.

[Content Ratio of Chlorine Ions]

Approximately 10 g of the ethylene/α-olefin copolymer was accurately weighed in a glass container that had been sterilized and washed using an autoclave or the like, 100 ml of ultrapure water was added, the glass container was sealed, and then ultrasonic wave (38 kHz) extraction was carried out at room temperature for 30 minutes, thereby obtaining an extraction liquid. The obtained extraction liquid was analyzed using an ion chromatography device manufactured by Dionex Ltd. (trade name “ICS-2000”), thereby measuring the content ratio of chlorine ions in the ethylene/α-olefin copolymer.

[Extraction Amount into Methyl Acetate]

Approximately 10 g of the ethylene/α-olefin copolymer was accurately weighed, and Soxhlet extraction was carried out using methyl acetate at a temperature that was equal to or higher than the boiling point of methyl acetate. The extraction amount of the ethylene/α-olefin copolymer into methyl acetate was computed using the weight difference of the ethylene/α-olefin copolymer before and after the extrusion or the residue amount obtained after the extracted solvent was volatilized.

[Volume Resistivity]

After the obtained sheet was cut into a size of 10 cm×10 cm, the sheet was laminated using a lamination apparatus (LM-110×160S manufactured by Seiko NPC Corporation) at 150° C. and 250 Pa for three minutes and at 150° C. and 100 kPa for 15 minutes, thereby producing a crosslinked sheet for measurement. The volume resistivity (Ω·cm) of the produced crosslinked sheet was measured at an applied voltage of 500 Von the basis of JIS K6911. Meanwhile, during the measurement, the temperature was set to 100±2° C. using a high-temperature measurement chamber “12708” (manufactured by Advantest Corporation), and a microammeter “R8340A” (manufactured by Advantest Corporation) was used.

[Sheet Blocking Properties]

Two sample sheets were laminated with the embossed surfaces facing upward, the embossed surfaces were made to face upward in a configuration of glass plate/sheet sample/sheet sample/glass plate, and a 400 g weight was placed on the glass plate. The samples were left to stand for 24 hours in an oven of 40° C., were removed and cooled at room temperature, and the peeling strength of the sheet was measured. The measurement was carried out using a tensile tester manufactured by Instron Corporation (product name “Instron 1123”) under conditions of a peeling angle between the sheets of 180 degrees, a span distance of 30 mm, a tensile speed of 10 mm/minute, and 23° C. An average value of three measured values was employed, and the sheet blocking properties were evaluated according to the following standards.

Favorable (A): the peeling strength was less than 50 gf/cm

Slightly blocked (B): the peeling strength was in a range of 50 gf/cm to 100 gf/cm

Blocked (C): the peeling strength was more than 100 gf/cm

(2) Synthesis of the Ethylene/α-Olefin Copolymer

### Synthesis Example 1

A toluene solution of methyl aluminoxane was supplied as a co-catalyst at a rate of 8.0 mmol/hr, a hexane slurry of bis(1,3-dimethylcyclopentadienyl)zirconium dichloride and a hexane solution of triisobutylaluminum were supplied at rates of 0.025 mmol/hr and at 0.5 mmol/hr respectively as main catalysts to one supply opening of a continuous polymerization vessel having stirring blades and an inner volume of 50 L, and n-hexane which was used as a catalyst solution and a polymerization solvent and was dehydrated and purified so that the total amount of the dehydrated and purified n-hexane became 20 L/hr. At the same time, ethylene, 1-butene and hydrogen were continuously supplied at rates of 3 kg/hr, 15 kg/hr and 5 NL/hr respectively to another supply opening of the polymerization vessel, and continuous solution polymerization was carried out under conditions of a polymerization temperature of 90° C., a total pressure of 3 MPaG, and a retention time of 1.0 hour. A n-hexane/toluene mixture solution of the ethylene/α-olefin copolymer generated in the polymerization vessel was continuously exhausted through an exhaust opening provided in the bottom portion of the polymerization vessel, and was guided to a coupling pipe in which a jacket portion was heated using 3 kg/cm² to 25 kg/cm² of steam so that the n-hexane/toluene mixture solution of the ethylene/α-olefin copolymer reached a temperature in a range of 150° C. to 190° C. Meanwhile, a supply opening through which methanol that was a catalyst-devitalizing agent was injected was provided immediately before the coupling pipe, and methanol was injected at a rate of approximately 0.75 L/hr so as to combine with the n-hexane/toluene mixture solution of the ethylene/α-olefin copolymer. The n-hexane/toluene mixture solution of the ethylene/α-olefin copolymer maintained at approximately 190° C. in the steam jacket-equipped coupling pipe was continuously sent to a flash chamber by adjusting the degree of the opening of a pressure control valve provided at the terminal portion of the coupling pipe so as to maintain approximately 4.3 MPaG. Meanwhile, when the n-hexane/toluene mixture solution was sent to the flash chamber, the solution temperature and the degree of the opening of the pressure-adjusting valve were set so that the pressure in the flash chamber was maintained at approximately 0.1 MPaG and the temperature of a vapor portion in the flash chamber was maintained at approximately 180° C. After that, a strand was cooled in a water vessel using a single screw extruder in which the die temperature was set to 180° C., and the strand was cut using a pellet cutter, thereby obtaining an ethylene/α-olefin copolymer in a pellet form. The yield was 2.2 kg/hr. The properties are described in Table 1.

### Synthesis Example 2

An ethylene/α-olefin copolymer was obtained in the same manner as in Synthesis Example 1 except for the facts that a hexane solution of [dimethyl(t-butylamide)(tetramethyl-n5-cyclopentadienyl)silane]titanium dichloride was supplied at a rate of 0.012 mmol/hr as a main catalyst, a toluene solution of triphenylcarbenium(tetrakis-pentafluorophenyl)borate and a hexane solution of triisobutylaluminum were supplied at rates of 0.05 mmol/hr and 0.4 mmol/hr respectively as co-catalysts, and 1-butene and hydrogen were supplied at rates of 5 kg/hr and 100 NL/hr respectively. The yield was 1.3 kg/hr. The properties are described in Table 1.

### Synthesis Example 3

An ethylene/α-olefin copolymer was obtained in the same manner as in Synthesis Example 1 except for the fact that a hexane solution of bis(p-tolyl)methylene(cyclopentadienyl)(1,1,4,4,7,7,10,10-octamethyl-1,2,3,4,7,8,9,10-octahydrodibenzo(b,h)-fluorenyl)zirconium dichloride was supplied as a main catalyst at a rate of 0.003 mmol/hr; a toluene solution of methylaluminoxane and a hexane solution of triisobutylaluminum were supplied at rates of 3.0 mmol/hr and 0.6 mmol/hr respectively as co-catalysts; ethylene was supplied at a rate of 4.3 kg/hr; 1-octane was supplied at a rate of 6.4 kg/hr instead of 1-butene; and dehydrated and purified n-hexane was continuously supplied so that the total amount of 1-octene and the dehydrated and purified n-hexane which was used as a catalyst solution and a polymerization solvent became 20 L/hr; hydrogen was supplied at a rate of 60 NL/hr; and the polymerization temperature was set to 130° C. The yield was 4.3 kg/hr. The properties are described in Table 1.

TABLE 1

| | | Synthesis | Synthesis |
|---|---|---|---|
| | Synthesis example 1 | example 2 | example 3 |
| α-Olefin type | 1-butene | 1-butene | 1-octene |
| Content ratio of | 14 | 17 | 11 |
| α-olefin unit [mol %] | | | |
| Content ratio of | 86 | 83 | 89 |
| ethylene unit [mol %] | | | |
| Density [g/cm³] | 0.870 | 0866 | 0.884 |
| MFR [g/10 minutes] | 20 | 11 | 48 |
| Shore A hardness [—] | 70 | 62 | 84 |
| B value [—] | 1.11 | 1.07 | 1.16 |
| Tαβ/Tαα [—] | <0.01 | 0.4 | <0.01 |
| Mw/Mn [—] | 2.2 | 2.2 | 2.1 |
| Content ratio of | 1 | 0.4 | 0.1 |
| chlorine ions [ppm] | | | |
| Extraction amount into | 0.7 | 1.8 | 0.8 |
| methyl acetate | | | |
| [weight %] | | | |
| Al residue amount [ppm] | 102 | 8 | 23 |

(3) Manufacturing of Encapsulating Material for a Solar Cell (Sheet)

### Manufacturing Example 1

0.5 parts by weight of γ-methacryloxypropyltrimethoxysilane as the ethylenic unsaturated silane compound, 1.0 part by weight of t-butylperoxy-2-ethylhexyl carbonate having a one-minute half-life temperature of 166° C. as the organic peroxide, 1.2 parts by weight of triallyl isocyanurate as the crosslinking aid, 0.4 parts by weight of 2-hydroxy-4-n-octyloxybenzophenone as the ultraviolet absorber, 0.2 parts by weight of bis(2,2,6,6-tetramethyl-4-piperidyl)sebacate as the radical scavenger, 0.05 parts by weight of tris(2,4-di-tert-butylphenyl)phosphite as the heat-resistant stabilizer 1, and 0.1 parts by weight of octadecyl-3-(3,5-di-tert-butyl-4-hydroxyphenyl)propionate as the heat-resistant stabilizer 2 were blended with 100 parts by weight of the ethylene/α-olefin copolymer of Synthetic Example 1.

A coat hanger T die (with a lip shape: 270 mm×0.8 mm) was mounted in a single screw extruder (with a screw diameter of 20 mmφ, L/D=28) manufactured by Thermoplastic Company, and molding was carried out at a roll temperature of 30° C. and a winding rate of 1.0 m/min under a condition of a die temperature of 100° C. using an embossing roll as a first cooling roll, thereby obtaining an embossed sheet (a sheet of the encapsulating material for a solar cell) having a thickness of 500 μm. The porosity of the obtained sheet was 28%. A variety of evaluation results of the obtained sheet are described in Table 2.

### Manufacturing Examples 2 and 3

Embossed sheets (sheets of the encapsulating material for a solar cell) were obtained in the same manner as in Example 1 except for the fact that the components were blended as described in Table 2. The porosities of the obtained sheets were all 28%. A variety of evaluation results of the obtained sheets are described in Table 2.

TABLE 2

| | | | Manufac- | Manufac- | Manufac- |
|---|---|---|---|---|---|
| | | | turing | turing | turing |
| | | | Example 1 | Example 2 | Example 3 |
| Formulation | Ethylene/ | Synthesis | 100 | | |
| (parts by | α-olefin | Example 1 | | | |
| weight) | copolymer | Synthesis | | | 100 |
| | | Example 2 | | | |
| | | Synthesis | | 100 | |
| | | Example 3 | | | |

| | | | | |
|---|---|---|---|---|
| | Ethylenic unsaturated | 0.5 | 0.5 | 0.5 |
| | silane compound | | | |
| | Organic peroxide | 1.0 | 1.0 | 1.0 |
| | Crosslinking aid | 1.2 | 1.2 | 1.2 |
| | Ultraviolet absorbent | 0.4 | 0.4 | 0.4 |
| | Radical scavenger | 0.2 | 0.2 | 0.2 |
| | Heat-resistant | 0.05 | 0.1 | 0.1 |
| | stabilizer 1 | | | |
| | Heat-resistant | 0.1 | 0.1 | 0.1 |
| | stabilizer 2 | | | |
| Evaluation | Volume resistivity @ | 2.0 × 10¹⁵ | 2.4 × 10¹⁵ | 4.1 × 10¹⁵ |
| | 100° C. [Ω · cm] | | | |
| | Sheet blocking | A | A | B |
| | properties | | | |

### Example 1

A mini module in which 18 single crystalline cells were connected to each other in series was produced using the encapsulating material for a solar cell of Manufacturing Example 1. A 3.2 mm-thick embossed and thermally-treated glass plate obtained by cutting a white float glass plate manufactured by AGC Fabritech Co., Ltd. into a size of 24 cm×21 cm was used as the glass plate. A cell having a light-incident surface-side busbar silver electrode in the center was cut into a size of 5 cm×3 cm, and was used as a crystalline cell (a single crystalline cell manufactured by Shinsung Solar Energy Co., Ltd.). Eighteen cells were connected in series using a copper ribbon electrode obtained by coating the surface of a copper foil with eutectic solder. A PET-based backsheet including silica-deposited PET was used as the back sheet, an approximately 2 cm-long cut was made in a part of the backsheet using a cutter knife as an extraction portion from the cell, and a positive terminal and a negative terminal of the 18 cells connected in series were extracted. The components were laminated using a vacuum laminator (LM-110×160-S manufactured by Seiko NPC Corporation) under conditions of a hot plate temperature of 150° C., a vacuum time of three minutes and a pressurization time of 15 minutes. After that, the encapsulating material and the backsheet spreading out of the glass plate were cut, an end surface encapsulating material was supplied to the glass plate edge, thereby allowing attachment of an aluminum frame, and RTV silicone was supplied and cured at the cut portions of the terminal portion extracted from the backsheet.

### Example 2

A mini module was produced in the same manner as in Example 1 except for the fact that the encapsulating material for a solar cell described in Manufacturing Example 3 was used.

### Example 3

A mini module was produced in the same manner as in Example 1 except for the fact that the encapsulating material for a solar cell described in Manufacturing Example 2 was used.

### Comparative Example 1

1. Synthesis of Modified Polyvinyl Acetal Resin

100 g of polyvinyl alcohol (manufactured by Kuraray Co., Ltd., PVA-117) having an ethylene content of 15 mol %, a saponification degree of 98 mol %, and an average polymerization degree of 1700 was dissolved in distilled water, thereby obtaining an aqueous solution of polyvinyl alcohol having a concentration of 10 weight %. 32 g of 35 weight % hydrochloric acid was added while stirring the aqueous solution in a state of being set at 40° C. using anchor-type stirring blades, and 60 g of butyl aldehyde was added dropwise. After the precipitation of the polyvinyl acetal resin in the aqueous solution was confirmed, the aqueous solution was heated to 50° C. and was stirred for four hours while 64 g of 35 weight % hydrochloric acid was added, thereby completing the reaction, and obtaining a dispersion fluid of a modified polyvinyl acetal resin. The obtained dispersion fluid was cooled, was neutralized using an aqueous solution of 30 weight % sodium hydroxide so as to reach a pH of the dispersion fluid of 7.5, was filtered, was washed using distilled water in an amount that was 20 times larger than the amount of the polymer, and was dried, thereby obtaining a modified polyvinyl acetal resin having an average polymerization degree of 1700 and an acetylation degree of 65 mol %.

2. Production of Encapsulating Material for a Solar Cell and Solar Cell Module

100 parts by mass of the modified polyvinyl acetal resin and 30 parts by mass of triethylene glycol-di-2-ethylhexanoate were kneaded under conditions of 100° C. and 30 rpm for five minutes using a LaboPlasto mill (manufactured by Toyo Seiki Co., Ltd.), thereby obtaining a modified polyvinyl acetal resin composition. Using the obtained composition, a sheet was set inside a 0.5 mm-thick SUS metal frame having a 25 cm×25 cm opening section using a vacuum laminator, and a flat sheet was produced with a vacuum time of three minutes and a pressurization time of ten minutes at a hot plate temperature of 100° C. The volume resistivity of the sheet was a lower resistance value than the measurement limitation at 100° C., which was a volume resistivity of equal to or less than 1×10⁸ Ω·cm. In addition, a mini module was produced using the sheet in the same manner as in Example 1 except for the fact that only the hot plate temperature of the laminator was set to 125° C.

[Volume Resistance]

Specimens including one crystalline cell out of eighteen crystalline cells connected to each other in series in the mini modules of Examples 1 to 3 and Comparative Example 1 were cut into a size of approximately 10 cm×10 cm using a water jet cutter, and then specimens having a configuration of glass plate/light-incident surface-side encapsulating layer/cell/back surface-side encapsulating layer/backsheet were obtained. Light-incident surface-side leads for electrode connection were removed from the end portions thereof from the copper ribbon sections of the interconnectors that connected the cells in the specimens. Specifically, a part of the backsheet, a part of the encapsulating material, and as necessary, a part of the cell on the copper ribbon that was present in the glass edge section were cut, a similarly solder-coated copper ribbon was soldered, and the component was used as an extraction lead. The specimen was placed in a constant temperature tank at 85° C., one electrode of a resistance measurement device was connected to the cell, and the other electrode was connected to the glass plate through a conductive rubber piece having a size corresponding to the electrode, whereby the volume resistance of the light-incident surface-side encapsulating layer was measured. At this time, the glass side of the specimen was connected to a large electrode side of the positive terminal, and the extraction lead from the cell was connected to the negative terminal. After the application of the voltage, a value obtained by standardizing the value after 1000 seconds using the cell area was calculated. The results are illustrated in Table 3. A resistivity chamber 12708 manufactured by ADC Corporation was used as the constant temperature tank, and a digital ultrahigh resistance/microammeter 8340A manufactured by ADC Corporation was used as the volume resistance measurement apparatus.

[PID Evaluation]

The positive terminals and the negative terminals of the mini modules of Examples 1 to 3 and Comparative Example 1 were short-circuited, and a high voltage-side cable of a power supply was connected. In addition, a low voltage-side cable of the power supply was connected to the aluminum frame, and the aluminum frame was grounded. The modules were set in a constant temperature and humidity tank at 85° C. and 85% rh, −600 V was applied after waiting for an increase in the temperature, and then the modules were held under the application of the voltage. A HARb-3R10-LF manufactured by Matsusada Precision Inc. was used as a high-voltage power supply, and an FS-214C2 manufactured by Etac Engineering Co., Ltd. was used as the constant temperature and humidity tank. After the application of the voltage for 24 hours and 240 hours, the IV characteristics of the modules were evaluated using a xenon light source having a light intensity distribution of an air mass (AM) 1.5 class A. A PVS-116i-S manufactured by Nisshinbo Mechatronics Inc. was used in the IV evaluation. The proportions (%) of the changes in the maximum output power Pmax of the IV characteristics after the test compared with the initial value are described in Table 3.

TABLE 3

| | | | | | Com- |
|---|---|---|---|---|---|
| | | | | | parative |
| | | Example 1 | Example 2 | Example 3 | Example 1 |
| Volume resistance | | 1.3 × 10¹⁴ | 1.5 × 10¹⁴ | 2.4 × 10¹³ | ≦1 × 10⁹ |
| (Ω · cm²) | | | | | |
| PID | Change | ≦1% | ≦1% | ≦1% | 6% |
| evaluation | after voltage | | | | |
| | application | | | | |
| | for 24 hours | | | | |
| | Change | ≦1% | ≦1% | ≦1% | |
| | after voltage | | | | |
| | application | | | | |
| | for | | | | |
| | 240 hours | | | | |

In the modules of Examples 1 to 3, the amount of change of Pmax after the high-pressure test remained at equal to or less than 1%, which was a favorable result. However, in the module of Comparative Example 1, the amount of decrease of Pmax after the application of the voltage for 24 hours was 6%, and the characteristics deteriorated.

Priority is claimed based on Japanese Patent Application No. 2012-087735, filed on Apr. 6, 2012, the content of which is incorporated herein by reference.

1. A solar cell module comprising:
a light-incident surface protective member;
a back surface protective member;
solar cell, elements; and
an encapsulating layer that encapsulates the solar cell elements between the light-incident surface protective member and the back surface protective member,
wherein a volume resistance per square centimeter at 85° C. between the light-incident surface protective member and the solar cell element is in a range of 1×10¹³ Ω·cm² to 1×10¹⁷ Ω·cm².

2. The solar cell module according to claim 1,
wherein the encapsulating layer includes
a light-incident surface-side encapsulating layer provided between the light-incident surface protective member and the solar cell elements and
a back surface-side encapsulating layer provided between the back surface protective member and the solar cell elements, and
a volume resistance per square centimeter at 85° C. of the light-incident surface-side encapsulating layer is in a range of 1×10¹³ Ω·cm² to 1×10¹⁷ Ω·cm².

3. The solar cell module according to claim 2,
wherein a thickness of at least the light-incident surface-side encapsulating layer is equal to or less than 1 cm.

4. The solar cell module according to claim 2,
wherein a volume resistivity, which is measured at a temperature of 100° C. and an applied voltage of 500 V on the basis of JIS K6911, of the light-incident surface-side encapsulating layer is in a range of 1.0×10¹³ Ω·cm to 1×10¹⁸ Ω·cm.

5. The solar cell module according to claim 2,
wherein the light-incident surface-side encapsulating layer is formed by crosslinking a resin composition containing an ethylene/α-olefin copolymer.

6. The solar cell module according to claim 1,
wherein the volume resistivity, which is measured at a temperature of 100° C. and an applied voltage of 500 V on the basis of JIS K6911, of the entire encapsulating layer is in a range of 1.0×10¹³ Ω·cm to 1×10¹⁸ Ω·cm.

7. The solar cell module according to claim 1,
wherein the entire encapsulating layer is formed by crosslinking a resin composition containing an ethylene/α-olefin copolymer.

8. The solar cell module according to claim 5,
wherein the ethylene/α-olefin copolymer satisfies at least one of the following requirements a1) to a4),
a1) a content ratio of a structural unit derived from ethylene is in a range of 80 mol % to 90 mol %, and a content ratio of a structural unit derived from an α-olefin having 3 to 20 carbon atoms is in a range of 10 mol % to 20 mol %,
a2) MFR, which is on the basis of ASTM D1238 and measured under conditions of a temperature of 190° C. and a load of 2.16 kg, is in a range of 0.1 g/10 minutes to 50 g/10 minutes,
a3) a density, which is measured on the basis of ASTM D1505, is in a range of 0.865 g/cm³ to 0.884 g/cm³, and
a4) a Shore A hardness, which is measured on the basis of ASTM D2240, is in a range of 60 to 85.
